(19) United States
(12) Patent Application Publication
(10) Pub. No.: US 2024/0393692 A1
(43) Pub. Date: Nov. 28, 2024

(54) RESIST TOPCOAT COMPOSITION, AND METHOD OF FORMING PATTERNS USING THE COMPOSITION

(71) Applicant: SAMSUNG SDI CO., LTD., Yongin-si (KR)

(72) Inventors: Hyeon PARK, Suwon-si (KR); Ran NAMGUNG, Suwon-si (KR); Kyoungjin HA, Suwon-si (KR); Daeseok SONG, Suwon-si (KR); Minsoo KIM, Suwon-si (KR)

(21) Appl. No.: 18/624,406

(22) Filed: Apr. 2, 2024

(30) Foreign Application Priority Data
May 22, 2023 (KR) 10-2023-0065730

(51) Int. Cl. G03F 7/11; C08F 220/28; C09D 133/14

(52) U.S. Cl. CPC G03F 7/11; C08F 220/282; C09D 133/14

(57) ABSTRACT

A resist topcoat composition and a method of forming patterns using the resist topcoat composition are provided. The resist topcoat composition includes a copolymer including a first structural unit represented by Chemical Formula M-1, a second structural unit represented by Chemical Formula M-2, and a third structural unit including at least one of structural units represented by Chemical Formula M-3A, Chemical Formula M-3B, Chemical Formula M-3C, and Chemical Formula M-3D; and a solvent.

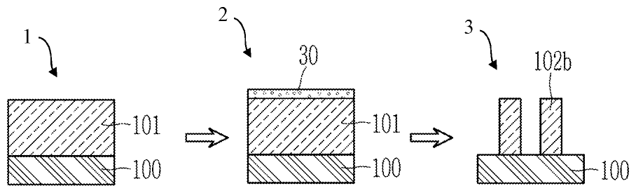

### CROSS-REFERENCE TO RELATED APPLICATION

This application claims priority to and the benefit of Korean Patent Application No. 10-2023-0065730, filed on May 22, 2023, in the Korean Intellectual Property Office, the entire content of which is incorporated herein by reference.

### BACKGROUND

### 1. Field

This disclosure relates to a resist topcoat composition, and a method of forming patterns utilizing the same.

### 2. Description of the Related Art

Recently, the semiconductor industry has developed the utilization of an ultrafine technique having a pattern with dimensions of a few nanometer, to several tens of nanometers in size. Implementation of a suitable ultrafine technique essentially requires (or there is a desire for) an effective photolithographic process capable of producing the proper dimensions.

A comparable photolithographic process includes forming a material layer on a semiconductor substrate, coating a photoresist layer thereon, exposing and developing to form a photoresist pattern, and then etching the material layer utilizing the photoresist pattern as a mask.

As photolithographic process techniques develop, a degree of pattern integration is increasing, and materials and technologies for solving the numerous challenges presented by the requirements (e.g., desires) of this process are continuously required.

If (e.g., when) extreme ultraviolet (EUV) wavelength light is irradiated onto (e.g., to) the photoresist, more, or less, than the intended quantity of light may be randomly irradiated in one or more regions. This may occur due to an excessive amount of energy per photon, which is termed a “photon shot noise.” The random irradiation may also be the result of an EUV absorption difference between the top and the bottom of the photoresist which may cause pattern distribution deterioration. For example, a photon shot noise or pattern distribution deterioration may result in deterioration of pattern roughness (e.g., LER: Line Edge Roughness, LWR: Line Width Roughness) or IPU (In-Point Uniformity), and/or the like. Accordingly, successful implementation of a photolithographic processes to enhance or improve pattern distribution deterioration requires (or there is a desire for) the development of improved resist topcoat composition technology.

### SUMMARY

One or more aspects of embodiments of the present disclosure are directed toward a resist topcoat composition that can prevent or reduce pattern deterioration and reduce pattern distribution.

One or more aspects of embodiments of the present disclosure are directed toward a method of forming patterns utilizing the resist topcoat composition.

Additional aspects will be set forth in part in the description which follows and, in part, will be apparent from the description, or may be learned by practice of the presented embodiments of the disclosure.

Some embodiments of the present disclosure provide a resist topcoat composition including a copolymer including a first structural unit represented by Chemical Formula M-1, a second structural unit represented by Chemical Formula M-2, and a third structural unit including: at least one selected from among structural units represented by Chemical Formula M-3A, Chemical Formula M-3B, Chemical Formula M-3C, and Chemical Formula M-3D; and a solvent.

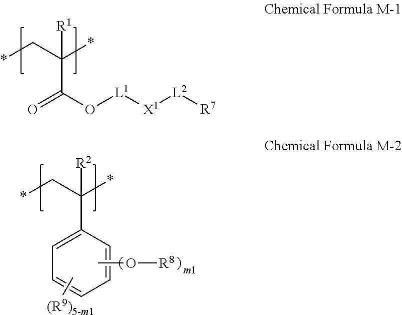

In Chemical Formula M-1 and Chemical Formula M-2,
R¹ and R² may each independently be hydrogen or a substituted or unsubstituted C1 to C10 alkyl group,
L¹ and L² may each independently be a single bond, a substituted or unsubstituted C1 to C10 alkylene group, or a combination thereof,
X¹ is a single bond, O, S, S(O), S(O)₂, C(O), (CO)O, O(CO), O(CO)O, NR^{a} (wherein, R^{a} may be hydrogen, deuterium, or a C1 to C10 alkyl group), or a combination thereof,
R⁷ may be hydrogen, fluorine, a hydroxyl group, a substituted or unsubstituted C1 to C20 alkyl group, or a combination thereof,
R⁸ may be hydrogen, or C(═O)R^{b},
R^{b} may be a substituted or unsubstituted C1 to C10 alkyl group,
at least one selected from among R⁷, L¹, and L² includes fluorine and a hydroxyl group,
R⁹ may each independently be hydrogen, a halogen, a hydroxyl group, a substituted or unsubstituted C1 to C10 alkyl group, or a combination thereof, and
m1 may be an integer of 1 to 4,

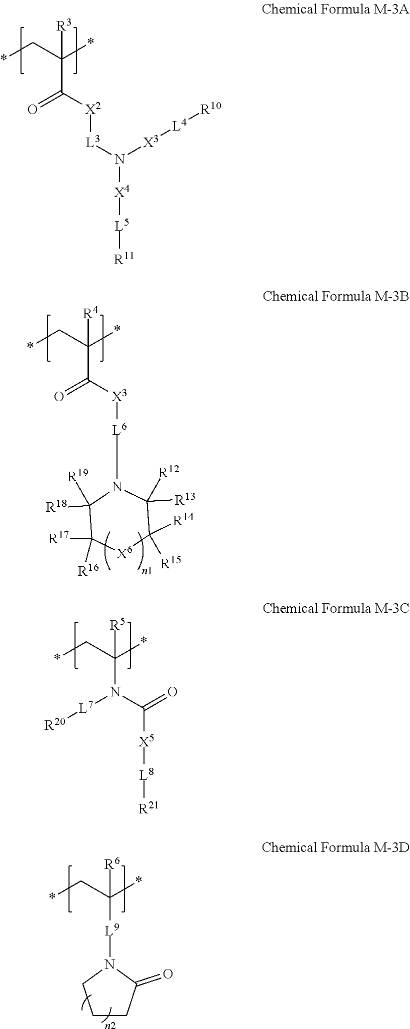

In Chemical Formula M-3A to Chemical Formula M-3D,
R³ to R⁶ may each independently be hydrogen or a substituted or unsubstituted C1 to C10 alkyl group,
R¹⁰ and R¹¹ may each independently be hydrogen, a hydroxyl group, a substituted or unsubstituted C1 to C20 alkyl group, a substituted or unsubstituted C6 to C20 aryl group, NR^{c}R^{d} (wherein, R^{c} and R^{d} may each independently be hydrogen, deuterium, or a C1 to C10 alkyl group), or a combination thereof,
R¹² to R²¹ may each independently be hydrogen, a substituted or unsubstituted C1 to C20 alkyl group, a substituted or unsubstituted C6 to C20 aryl group, NR^{c}R^{d} (wherein, R^{c} and R^{d} may each independently be hydrogen, deuterium, or a C1 to C10 alkyl group), or a combination thereof,
L³ to L⁹ may each independently be a single bond, a substituted or unsubstituted C1 to C10 alkylene group, a substituted or unsubstituted C6 to C12 arylene group, or a combination thereof,
X² and X⁵ may each independently be a single bond, O, or S,
X³ and X⁴ may each independently be a single bond, (CO)O, O(CO), or O(CO)O,
X⁶ may be a single bond, O, or CH₂,
n1 may be an integer of 0 or 1,
n2 may be an integer of 1 to 3, and
* may be a linking point.

The first structural unit may be represented by Chemical Formula 1.

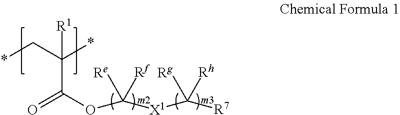

In Chemical Formula 1,
R¹ may be hydrogen or a substituted or unsubstituted C1 to C10 alkyl group,
R^{e}, R^{f}, R^{g}, R^{h}, and R⁷ may each independently be hydrogen, fluorine, a hydroxyl group, a substituted or unsubstituted C1 to C20 alkyl group, or a combination thereof,
m2 and m3 may each independently be an integer of 1 to 10,
X¹ may be a single bond, O, S, S(O), S(O)₂, C(O), (CO)O, O(CO), O(CO)O,
NR^{a} (wherein, R^{a} may be hydrogen, deuterium, or a C1 to C10 alkyl group), or a combination thereof, and
at least one selected from among R^{e}, R^{f}, R^{g}, R^{h}, and R⁷ includes fluorine and a hydroxyl group.

For example, at least one selected from among R^{g}, R^{h}, and R⁷ in Chemical Formula 1 includes a fluorine group and a hydroxyl group.

As a specific example, in Chemical Formula 1, at least one selected from among R^{g} and R^{h} may be fluorine or a C1 to C10 alkyl group substituted with at least one fluorine, and R⁷ may be a hydroxyl group or a C1 to C10 alkyl group substituted with at least one hydroxyl group.

As a specific example, in Chemical Formula 1, at least one selected from among R^{g} and R^{h} may be a hydroxyl group or a C1 to C10 alkyl group substituted with at least one hydroxyl group, and R⁷ may be fluorine or a C1 to C10 alkyl group substituted with at least one fluorine.

As a specific example, in Chemical Formula 1, R⁹ may be a hydroxyl group or a C1 to C10 alkyl group substituted with at least one hydroxyl group, R^{h} may be fluorine or a C1 to C10 alkyl group substituted with at least one fluorine, R⁷ may be a hydroxyl group, fluorine, or a C1 to C10 alkyl group substituted with at least one of one or more fluorine or one or more hydroxyl groups.

As a specific example, in Chemical Formula 1, at least one selected from among R^{g} and R^{h} may be fluorine or a C1 to C10 alkyl group substituted with at least one fluorine, and R⁷ may be a hydroxyl group or a C1 to C5 alkyl group substituted with at least one of one or more hydroxyl groups and one or more C1 to C5 fluoroalkyl groups.

The first structural unit may be selected from among Group I (e.g., at least one selected from among the structural units in Group I).

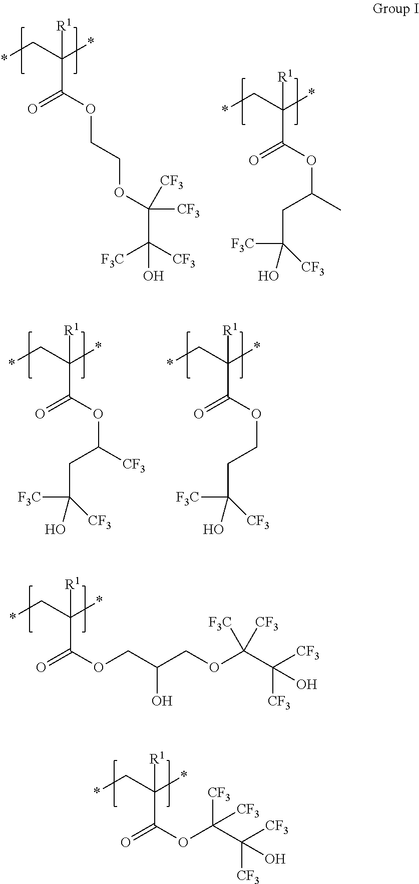

In Group I, R¹ may each independently be a hydrogen or a methyl group, and * is a linking point.

The second structural unit may be represented by any one of Chemical Formula 2-1 to Chemical Formula 2-4.

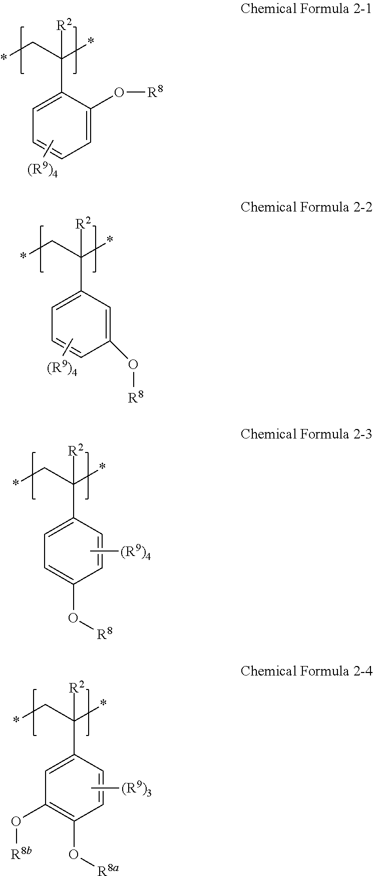

In Chemical Formula 2-1 to Chemical Formula 2-4,
R² may be hydrogen or a methyl group,
R⁸, R^{8a}, and R^{8b} may each independently be hydrogen, or C(═O)R^{b},
R^{b} may be a substituted or unsubstituted C1 to C5 alkyl group, m1 may be an integer of 1 to 4,
R⁹ may each independently be hydrogen, a halogen, a hydroxyl group, a substituted or unsubstituted C1 to C10 alkyl group, or a combination thereof, and
* may be a linking point.

At least one of R⁹ may be a halogen.

At least one of R⁹ may be an iodine group.

The second structural unit may be selected from among Group II (e.g., at least one selected from among the structural units in Group II).

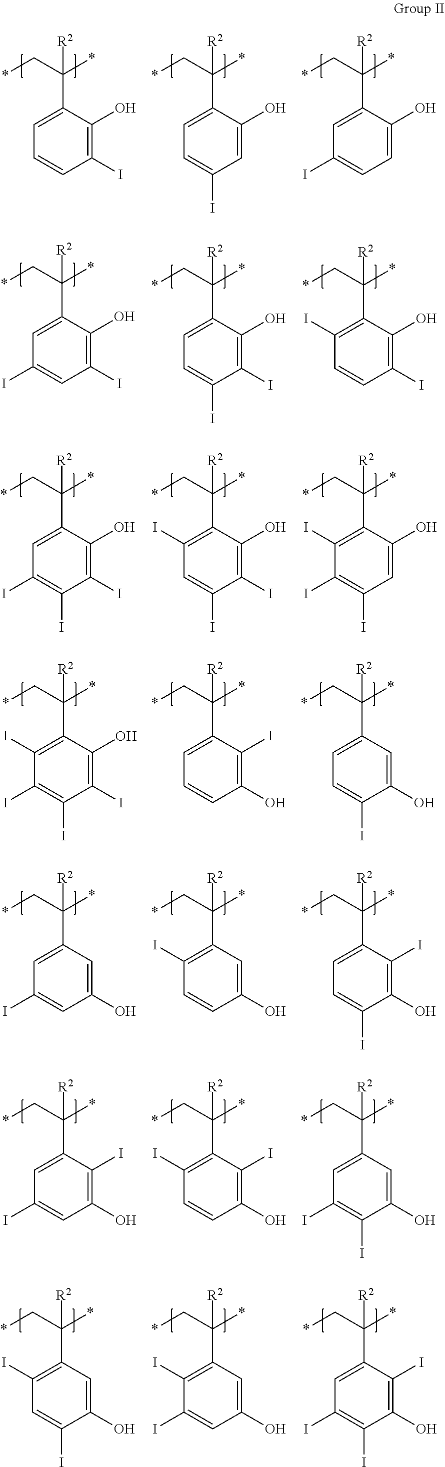

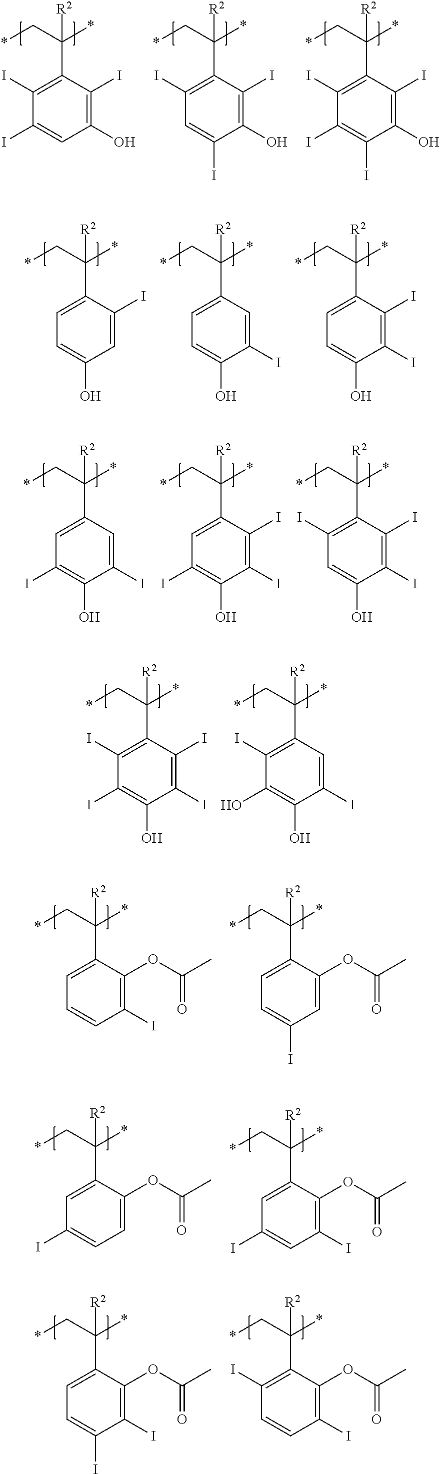

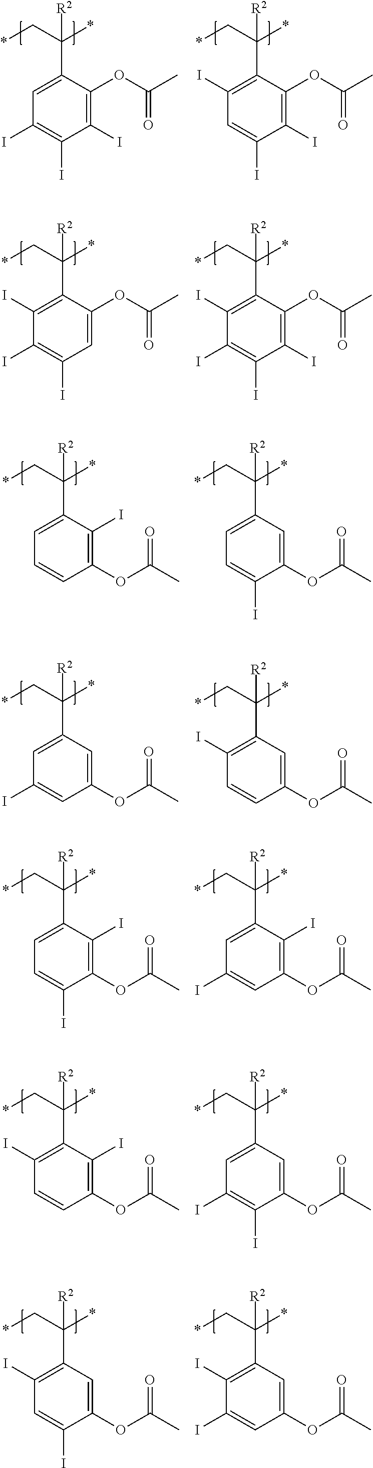

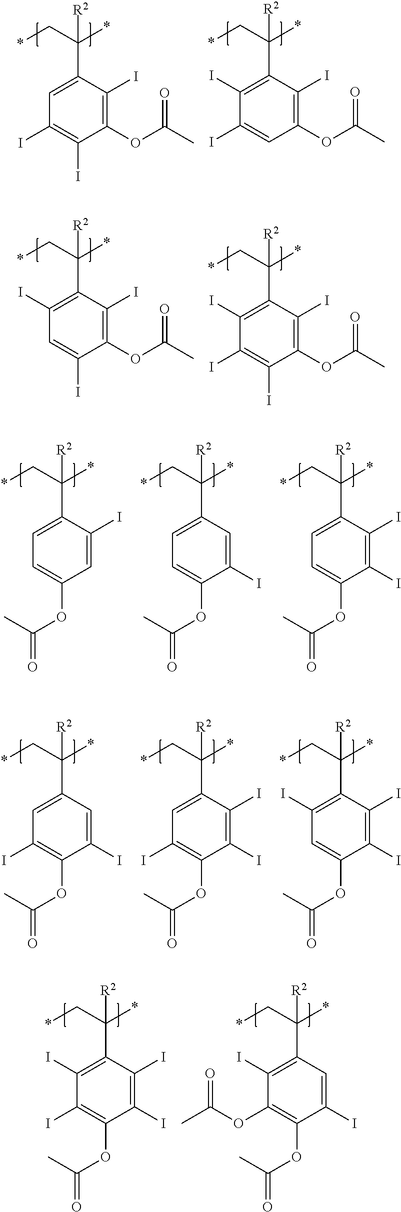

In Group II, R² may each independently be a hydrogen or methyl group, and * may be a linking point.
L³ to L⁹ may each independently be a single bond, a substituted or unsubstituted C1 to C5 alkylene group, or a substituted or unsubstituted phenylene group,
R¹⁰, R¹¹, R²⁰, and R²¹ may each independently be hydrogen, a hydroxyl group, a substituted or unsubstituted methyl group, a substituted or unsubstituted ethyl group, a substituted or unsubstituted n-propyl group, a substituted or unsubstituted isopropyl group, a substituted or unsubstituted n-butyl group, a substituted or unsubstituted tert-butyl group, a substituted or unsubstituted n-pentyl group, a substituted or unsubstituted neo-pentyl group, a substituted or unsubstituted phenyl group, NR^{c} (wherein, R^{c} is hydrogen, deuterium, or a C1 to C10 alkyl group), or a combination thereof, and
R¹² to R¹⁹ may each independently be hydrogen or a substituted or unsubstituted C1 to C10 alkyl group.

The third structural unit may be selected from among Group Ill (e.g., at least one selected from among the structural units in Group III).

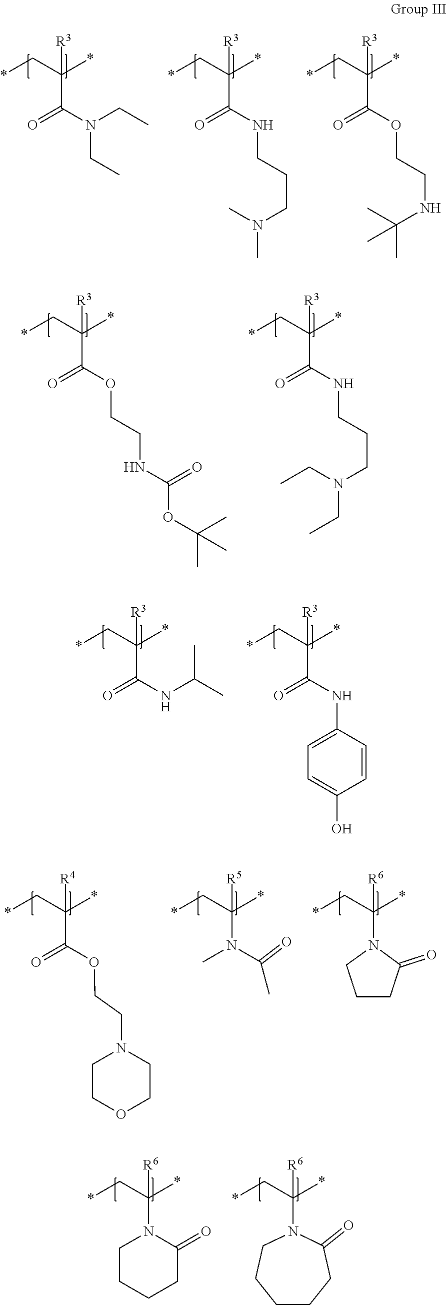

In Group III,
R³ to R⁶ may each independently be a hydrogen or a methyl group, and * is a linking point.

The copolymer may include 30 to 95 mol % of the first structural unit, about 1 to about 20 mol % of the second structural unit, and about 5 to about 50 mol % of the third structural unit, based on a total weight of the copolymer.

A weight average molecular weight of the copolymer may be about 1,000 g/mol to about 50,000 g/mol.

The copolymer may be included in the resist topcoat composition in an amount of about 0.1 wt % to about 10 wt % based on a total weight of the resist topcoat composition.

In some embodiments, a pH of the resist topcoat composition may be about 3 to about 12.

In one embodiment, the copolymer may be selected from among compounds listed in Group IV (e.g., the copolymer may be at least one selected from among Group IV).

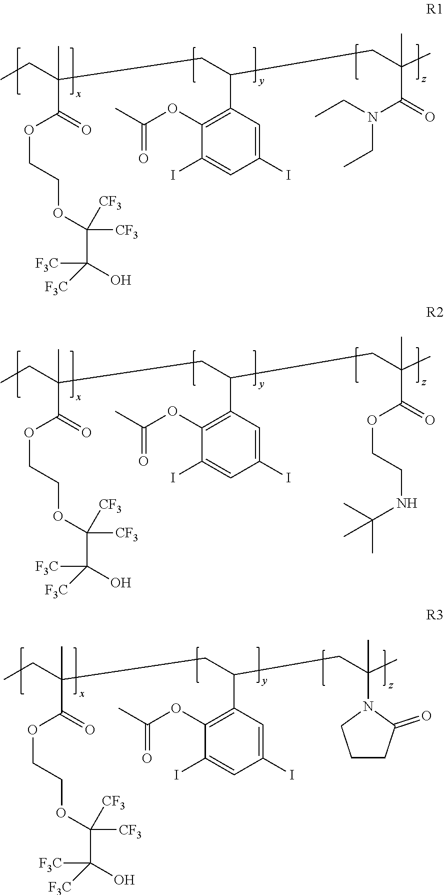

In Group IV, x: y: z may be 66:10:24 or 68:10:22 or 69:10:21.

The solvent may be an ether-based solvent represented by Chemical Formula 4.

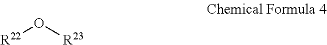

In Chemical Formula 4,
R²² and R²³ may each independently be a substituted or unsubstituted C3 to C20 alkyl group.

The ether-based solvent may be selected from among diisopropyl ether, dipropyl ether, diisoamyl ether, diamyl ether, dibutyl ether, diisobutyl ether, di-sec-butyl ether, dihexyl ether, bis(2-ethylhexyl) ether, didecyl ether, diundecyl ether, didodecyl ether, ditetradecyl ether, hexadecyl ether, butyl methyl ether, butyl ethyl ether, butyl propyl ether, tert-butyl methyl ether, tert-butyl ethyl ether, tert-butylpropyl ether, di-tert-butyl ether, cyclopentylmethyl ether, cyclohexylmethyl ether, cyclopentylethyl ether, cyclohexylethyl ether, cyclopentylpropyl ether, cyclopentyl-2-propyl ether, cyclohexylpropyl ether, cyclohexyl-2-propyl ether, cyclopentylbutyl ether, cyclopentyl-tert-butyl ether, cyclohexylbutyl ether, cyclohexyl-tert-butyl ether, 2-octanone, 4-heptanone, and a combination thereof.

In another embodiment, a method of forming patterns includes coating a photoresist composition on a substrate and heating to form a photoresist film, coating the aforementioned resist topcoat composition on the photoresist film and heating to form a photoresist topcoat, and exposing and developing the photoresist topcoat and the photoresist film to form the patterns.

The resist topcoat composition described herein is configured to remove excessively activated acid from the top of the photoresist to prevent or reduce the pattern distribution deterioration (e.g., such as deterioration of roughness (LER, LWR) or IPU, and/or the like due to the difference in EUV absorption between top and bottom of the photoresist). The resist topcoat composition described herein is configured to improve the distribution and also greatly improve IPU of Pillar patterns. Accordingly, the resist topcoat composition may be advantageously utilized to form fine patterns of the photoresist, e.g., if (e.g., when) the resist topcoat composition according to some embodiments is exposed to light by EUV.

### BRIEF DESCRIPTION OF THE DRAWING

The accompanying drawing is included to provide a further understanding of the present disclosure, and is incorporated in and constitutes a part of this specification. The drawing illustrates an example embodiment, and facilitates explanation of the principles of the present disclosure, together with the detailed description.

Features will be apparent to those of skill in the art by describing in more detail example embodiments with reference to the attached drawing in which:

the drawing is a schematic view for explaining a method of forming patterns utilizing a resist topcoat composition according to some embodiments.

### DETAILED DESCRIPTION

Example embodiments of the present disclosure will hereinafter be described in more detail, and may be easily performed by a person skilled in the art. However, this disclosure may be embodied in many different forms and is not construed as limited to the example embodiments set forth herein, rather the present disclosure is defined by the scope of claims. In this regard, the present embodiments may have different forms and should not be construed as being limited to the descriptions set forth herein, and it is to be appreciated that all changes, equivalents, and substitutes that do not depart from the spirit and technical scope are encompassed in the present disclosure.

In the drawing, the thickness of layers, films, panels, regions, and/or the like, are exaggerated for clarity and like reference numerals designate like elements throughout, and duplicative descriptions thereof may not be provided the specification. It will be understood that if (e.g., when) an element such as a layer, film, region, or substrate is referred to as being “on” another element, it can be directly on the other element or intervening elements may also be present. In contrast, if (e.g., when) an element is referred to as being “directly on” another element, there are no intervening elements present.

Unless otherwise defined, all chemical names, technical and scientific terms, and terms defined in common dictionaries should be interpreted as having meanings consistent with the context of the related art, and should not be interpreted in an ideal or overly formal sense. It will be understood that, although the terms first, second, and/or the like may be used herein to describe various elements, these elements should not be limited by these terms. These terms are only used to distinguish one element from another element. Thus, a first element could be termed a second element without departing from the teachings of the present disclosure. Similarly, a second element could be termed a first element.

As used herein, expressions such as “at least one of,” “one of,” “at least one selected from among,” and “selected from among,” if (e.g., when) preceding a list of elements, modify the entire list of elements and do not modify the individual elements of the list. As utilized herein, the expressions “at least one of A, B, or C”, “one of A, B, C, or a combination thereof” and “one of A, B, C, and a combination thereof” refer to each component and a combination thereof (e.g., A; B; A and B; A and C; B and C; or A, B, and C). For example, “at least one of a to c,” “at least one of a, b or c,” and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof.

As utilized herein, alternative language such as “or” is not to be construed as an exclusive meaning, for example, “A or B” is construed to include A, B, A+B, and/or the like. Similarly, the term “and/or” includes any and all combinations of one or more of the associated listed items. The symbol “/” utilized herein may be interpreted as “and” or “or” according to the context.

As utilized herein, it is to be understood that the terms such as “including,” “includes,” “include,” “having,” “has,” “have,” “comprises,” “comprise,” and/or “comprising” are intended to indicate the existence of the features, numbers, steps, actions, components, parts, ingredients, materials, or combinations thereof disclosed in the specification and are not intended to preclude the possibility that one or more other features, numbers, steps, actions, components, parts, ingredients, materials, or combinations thereof may exist or may be added. The term “combination thereof may include a mixture, a laminate, a complex, a copolymer, an alloy, a blend, a reactant of constituents.

As utilized herein, singular forms such as “a,” “an,” and “the” are intended to include the plural forms as well, unless the context clearly indicates otherwise.

As utilized herein, the terms “use,” “using,” and “used” may be considered synonymous with the terms “utilize,” “utilizing,” and “utilized,” respectively.

The term “may” will be understood to refer to “one or more embodiments of the present disclosure,” some of which include the described element and some of which exclude that element and/or include an alternate element.

In this context, “consisting essentially of” means that any additional components will not materially affect the chemical, physical, optical or electrical properties of the semiconductor film.

### Definitions

As utilized herein, if (e.g., when) a definition is not otherwise provided, “substituted” refers to replacement of a hydrogen atom of a compound by a substituent selected from among a halogen atom (F, Br, Cl, or I), a hydroxyl group, an alkoxy group, a nitro group, a cyano group, an amino group, an azido group, an amidino group, a hydrazino group, a hydrazono group, a carbonyl group, a carbamyl group, a thiol group, an ester group, a carboxyl group or a salt thereof, a sulfonic acid group or a salt thereof, a phosphoric acid group or a salt thereof, a vinyl group, a C1 to C20 alkyl group, a C2 to C20 alkenyl group, a C2 to C20 alkynyl group, a C6 to C30 aryl group, a C7 to C30 arylalkyl group, a C6 to C30 allyl group, a C1 to C30 alkoxy group, a C1 to C20 heteroalkyl group, a C3 to C20 heteroarylalkyl group, a C3 to C30 cycloalkyl group, a C3 to C15 cycloalkenyl group, a C6 to C15 cycloalkynyl group, a C3 to C30 heterocycloalkyl group, and a combination thereof.

As utilized herein, if (e.g., when) a definition is not otherwise provided, “hetero” refers to one including 1 to 10 heteroatoms selected from among N, O, S, and P.

Unless otherwise specified in the present specification, the weight average molecular weight is measured by dissolving a powder sample in tetrahydrofuran (THF) and then utilizing 1200 series Gel Permeation Chromatography (GPC) of Agilent Technologies (column is Shodex Company LF-804, standard sample is Shodex company polystyrene).

In some embodiments, unless otherwise defined in the specification, “*” indicates a linking point of a structural unit or a compound moiety of a compound.

Hereinafter, a resist topcoat composition according to some embodiments is described.

### Resist Topcoat Composition

The present disclosure relates to a resist (e.g., photoresist) topcoat composition capable of improving at least one of IPU (In-Point Uniformity) of C/H (contact hole) patterns, LER (line edge roughness) and/or LWR (line width roughness) of L/S (line and space) patterns, or improving IPU of Pillar patterns. In some embodiments, present disclosure relates to enhancing or improving the sensitivity of the photoresist (e.g., film) during the process of forming fine pattern through photolithography by utilizing high-energy electromagnetic radiation rays such as EUV (extreme ultraviolet; a wavelength of 13.5 nm) and/or the like and concurrently (e.g., simultaneously), selectively reducing an acid concentration in an upper portion of the photoresist (e.g., film). In some embodiments, the present disclosure relates to a method of forming patterns (e.g., resist (e.g., photoresist patterns) by utilizing the resist (e.g., photoresist) topcoat composition described herein.

For example, the resist topcoat composition according to some embodiments includes: a copolymer including a first structural unit represented by Chemical Formula M-1, a second structural unit represented by Chemical Formula M-2, and a third structural unit including at least one of structural units represented by Chemical Formula M-3A, Chemical Formula M-3B, Chemical Formula M-3C, and/or Chemical Formula M-3D; and a solvent.

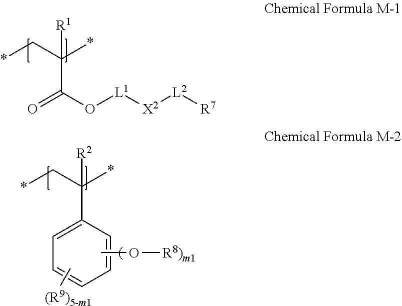

In Chemical Formula M-1 and Chemical Formula M-2,
R¹ and R² may each independently be hydrogen or a substituted or unsubstituted C1 to C10 alkyl group,
L¹ and L² may each independently be a single bond, a substituted or unsubstituted C1 to C10 alkylene group, or a combination thereof,
X¹ may be a single bond, O, S, S(O), S(O)₂, C(O), (CO)O, O(CO), O(CO)O, NR^{a} (wherein, R^{a} may be hydrogen, deuterium, or a C1 to C10 alkyl group), or a combination thereof,
R⁷ may be hydrogen, fluorine, a hydroxyl group, a substituted or unsubstituted C1 to C20 alkyl group, or a combination thereof,
R⁸ may each independently be hydrogen, or C(═O)R^{b},
R^{b} may be a substituted or unsubstituted C1 to C10 alkyl group, at least one selected from among R⁷, L¹, and L² includes fluorine and a hydroxyl group,
R⁹ may each independently be hydrogen, a halogen, a hydroxyl group, a substituted or unsubstituted C1 to C10 alkyl group, or a combination thereof, and
m1 may be an integer of 1 to 4,

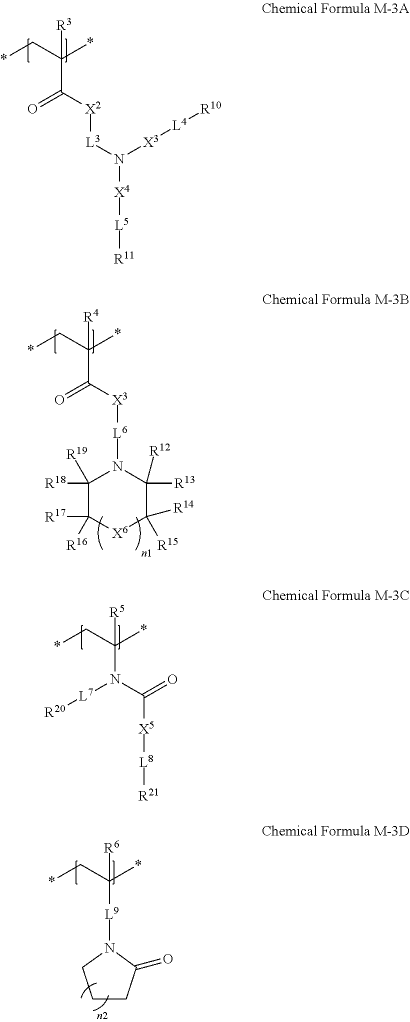

In Chemical Formula M-3A to Chemical Formula M-3D,
R³ to R⁶ may each independently be hydrogen or a substituted or unsubstituted C1 to C10 alkyl group,
R¹⁰ and R¹¹ may each independently be hydrogen, a hydroxyl group, a substituted or unsubstituted C1 to C20 alkyl group, a substituted or unsubstituted C6 to C20 aryl group, NR^{c}R^{d} (wherein, R^{c} and R^{d} may each independently be hydrogen, deuterium, or a C1 to C10 alkyl group), or a combination thereof,
R¹² to R²¹ may each independently be hydrogen, a substituted or unsubstituted C1 to C20 alkyl group, a substituted or unsubstituted C6 to C20 aryl group, NR^{c}R^{d} (wherein, R^{c} and R^{d} may each independently be hydrogen, deuterium, or a C1 to C10 alkyl group), or a combination thereof,
L³ to L⁹ may each independently be a single bond, a substituted or unsubstituted C1 to C10 alkylene group, a substituted or unsubstituted C6 to C12 arylene group, or a combination thereof,
X² and X⁵ may each independently be a single bond, —O— or —S—,
X³ and X⁴ may each independently be a single bond, —(CO)O—, —O(CO), or —O(CO)O—,
X⁶ may be a single bond, O, or CH₂,
n1 may be an integer of 0 or 1,
n2 may be an integer of 1 to 3, and
* may be a linking point.

The resist (e.g., photoresist) topcoat composition according to some embodiments, if (e.g., when) coated on a photoresist layer, may not only increase sensitivity of the photoresist but also greatly improve LER/LWR of L/S patterns, IPU of C/H patterns, and IPU of Pillar patterns.

In the resist topcoat composition, the first structural unit included in the copolymer may protect the photoresist, while minimally having an impact on the photoresist due to characteristics of being well dissolved in a solvent having almost no reactivity with the photoresist, the second structural unit may improve sensitivity by increasing EUV absorption, and the third structural unit includes a basic functional group to react with acid excessively produced by the exposure on the photoresist layer and thus reduce a concentration of the acid and may improve a round profile of the upper portion of the photoresist into a rectangular one to improve IPU or LWR of the patterns.

On the other hand, if (e.g., when) the resist (e.g., photoresist) topcoat composition remains after the development, there may be a problem of reducing a product yield by generating scum defects in L/S patterns or not-open defects in C/H patterns.

However, the resist (e.g., photoresist) topcoat composition according to some embodiments is removed during the development process, causing no defects in one or more suitable patterns.

In Chemical Formula M-2, if (e.g., when) m1 is 2 or more, each O—R⁸ may be the same or different from each other.

In Chemical Formula M-2, if (e.g., when)5-m1 is 2 or more, each R⁹ may be the same or different from each other.

In Chemical Formula M-3B, X⁶ may be a single bond, or n1 may be 0, which refers to that X⁶ is absent to form an N-containing five-membered ring.

The meaning that at least one selected from among R⁷, L¹, and L² includes a fluorine and a hydroxyl group may include the following case where
R⁷ may be selected from among:
at least one fluorine and a C1 to C10 alkyl group substituted with at least one hydroxyl group, or
at least one selected from among L¹ and L² may be a C1 to C10 alkylene group substituted with one or more fluorine and one or more hydroxyl groups, or
at least one selected from among L¹ and L² may be a C1 to C10 alkylene group substituted with one or more fluorine, and at least one of the others (e.g., L¹ or L²) may be a C1 to C10 alkylene group substituted with one or more hydroxyl groups, or
R⁷ may be fluorine, and at least one selected from among L¹ and L² may be a C1 to C10 alkylene group substituted with one or more hydroxyl groups, or
R⁷ may be a hydroxyl group, and at least one selected from among L¹ and L² may be a C1 to C10 alkylene group substituted with one or more fluorine, or
R⁷ may be a C1 to C10 alkyl group substituted with one or more fluorine and one or more hydroxyl groups, or
R⁷ may be a C1 to C10 alkyl group substituted with one or more hydroxyl groups and one or more C1 to C10 fluoroalkyl groups.

As an example, the first structural unit may be represented by Chemical Formula 1.

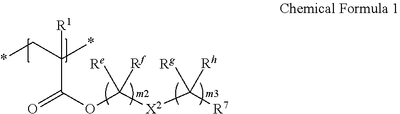

In Chemical Formula 1,
R¹ may be hydrogen or a substituted or unsubstituted C1 to C10 alkyl group,
R^{e}, R^{f}, R^{g}, R^{h}, and R⁷ may each independently be hydrogen, fluorine, a hydroxyl group, a substituted or unsubstituted C1 to C20 alkyl group, or a combination thereof,
m2 and m3 may each independently be an integer of 1 to 10,
X¹ may be a single bond, O, S, S(O), S(O)₂, C(O), (CO)O, O(CO), O(CO)O, NR^{a} (wherein, R^{a} may be hydrogen, deuterium, or a C1 to C10 alkyl group), or a combination thereof, and
at least one selected from among R^{e}, R^{f}, R^{g}, R^{h}, and R⁷ includes fluorine and a hydroxyl group.

In Chemical Formula 1, if (e.g., when) m2 is 2 or more, each R^{e} may be the same or different from each other.

In Chemical Formula 1, if (e.g., when) m2 is 2 or more, each R^{f} may be the same or different from each other.

In Chemical Formula 1, if (e.g., when) m3 is 2 or more, each R^{g} may be the same or different from each other.

In Chemical Formula 1, if (e.g., when) m3 is 2 or more, each R^{h} may be the same or different from each other.

The meaning that at least one selected from among R^{e}, R^{f}, R^{g}, R^{h}, and R⁷ includes fluorine and a hydroxyl group may include the following case where
at least one selected from among R^{e}, R^{f}, R^{g}, R^{h}, and R⁷ may each independently be fluorine and a hydroxyl group, or
at least one selected from among R^{e}, R^{f}, R^{g}, R^{h}, and R⁷ may each independently include a C1 to C10 alkyl group substituted with one or more fluorine and a C1 to C10 alkyl group substituted with one or more hydroxyl groups, or
at least one selected from among R^{e}, R^{f}, R^{g}, R^{h}, and R⁷ may each independently include one or more hydroxyl groups and one or more C1 to C10 alkyl groups substituted with fluorine, or
at least one selected from among R^{e}, R^{f}, R^{g}, R^{h}, and R⁷ may each independently include a C1 to C10 alkyl group substituted with one or more hydroxyl groups and one or more C1 to C10 fluoroalkyl groups, or at least one selected from among R^{e}, R^{f}, R^{g}, R^{h}, and R⁷ may be fluorine, and
at least one of the others (e.g., R^{e}, R^{f}, R^{g}, R^{h}, or R⁷) may be a hydroxyl group, or
at least one selected from among R^{e}, R^{f}, R^{g}, R^{h}, and R⁷ may be fluorine, and at least one of the others (e.g., R^{e}, R^{f}, R^{g}, R^{h}, or R⁷) may include a C1 to C10 alkyl group substituted with one or more hydroxyl groups, or
at least one selected from among R^{e}, R^{f}, R^{g}, R^{h}, and R⁷ may be a hydroxyl group, and at least one of the others (e.g., R^{e}, R^{f}, R^{g}, R^{h}, or R⁷) may include a C1 to C10 alkyl group substituted with one or more fluorine, or
at least one selected from among R^{e}, R^{f}, R^{g}, R^{h}, and R⁷ may be a C1 to C20 alkyl group substituted with one or more fluorine, and at least one of the others (e.g., R^{e}, R^{f}, R^{g}, R^{h}, or R⁷) may be a C1 to C20 alkyl group substituted with one or more hydroxyl groups.

For example, R¹ may be hydrogen or a methyl group,
X¹ may be a single bond, O, or NR^{a} (where R^{a} may be hydrogen, deuterium, or a C1 to C10 alkyl group), and
R⁷ may be fluorine, a hydroxyl group, a C1 to C10 alkyl group substituted with at least one fluorine, or a C1 to C10 alkyl group substituted with at least one hydroxyl group.

As an example, at least one selected from among R^{g}, R^{h}, and R⁷ in Chemical Formula 1 may include a fluorine group and a hydroxyl group.

As an example, in Chemical Formula 1, at least one of R^{g} or R^{h} may be fluorine or a C1 to C10 alkyl group substituted with at least one fluorine, and R⁷ may be a hydroxyl group or a C1 to C10 alkyl group substituted with at least one hydroxyl group.

As an example, in Chemical Formula 1, at least one of R^{g} or R^{h} may be a hydroxyl group or a C1 to C10 alkyl group substituted with at least one hydroxyl group, and R⁷ may be fluorine or a C1 to C10 alkyl group substituted with at least one fluorine.

As an example, in Chemical Formula 1, R^{g} may be a hydroxyl group or a C1 to C10 alkyl group substituted with at least one hydroxyl group, R^{h} may be fluorine or a C1 to C10 alkyl group substituted with at least one fluorine, and R⁷ may be a hydroxyl group, fluorine, or a C1 to C10 alkyl group substituted with at least one of fluorine or a hydroxyl group.

As an example, in Chemical Formula 1, at least one of R^{g} or R^{h} may be fluorine or a C1 to C10 alkyl group substituted with at least one fluorine, and R⁷ may be a hydroxyl group or a C1 to C5 alkyl group substituted with at least one of a hydroxyl group or a C1 to C5 fluoroalkyl group.

For example, the first structural unit may be selected from among Group I (e.g., at least one selected from among the structural units in Group I).

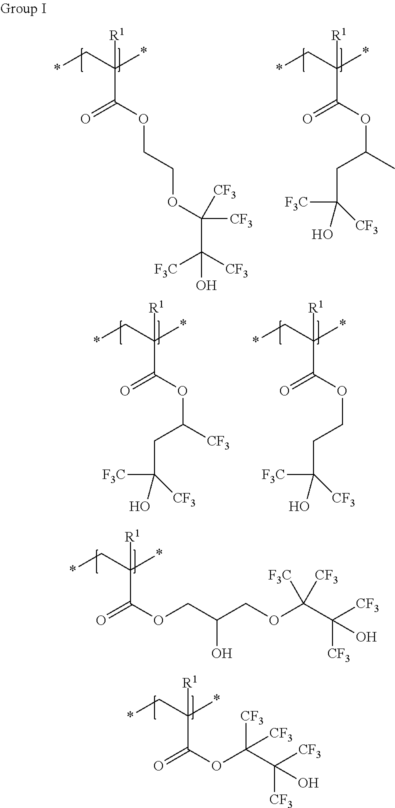

In Group I,
R¹ may each independently be hydrogen or a methyl group, and * may be a linking point.

As an example, the second structural unit may be represented by any one of Chemical Formula 2-1 to Chemical Formula 2-4.

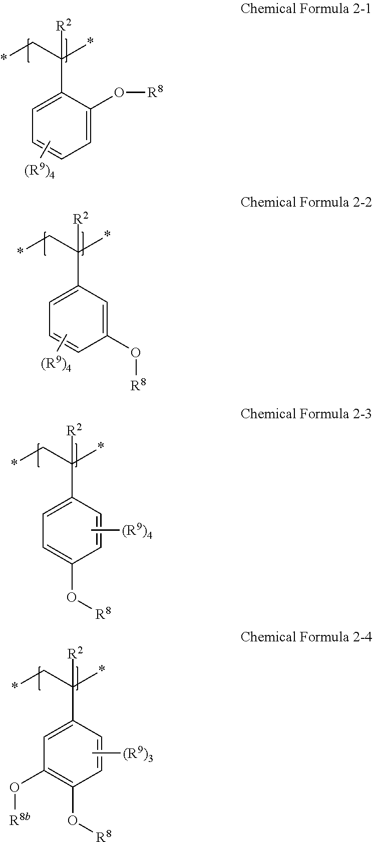

In Chemical Formula 2-1 to Chemical Formula 2-4,
R² may be hydrogen or a methyl group,
R⁸, R^{8a}, and R^{8b} may each independently be hydrogen, or C(═O)R^{b},
R^{b} may be a substituted or unsubstituted C1 to C5 alkyl group, m1 may be an integer of 1 to 4,
R⁹ may each independently be hydrogen, a halogen, a hydroxyl group, a substituted or unsubstituted C1 to C10 alkyl group, or a combination thereof, and
* may be a linking point.

In Chemical Formula 2-1 to Chemical Formula 2-4, each R⁹ may be different from or the same as each other.

As an example, at least one of R⁹ may be a halogen.

As a specific example, at least one of R⁹ may be an iodine group.

If (e.g., when) the second structural unit includes an iodine group, sensitivity can be further improved.

For example, the second structural unit may be selected from among Group II (e.g., at least one selected from among the structural units in Group II).

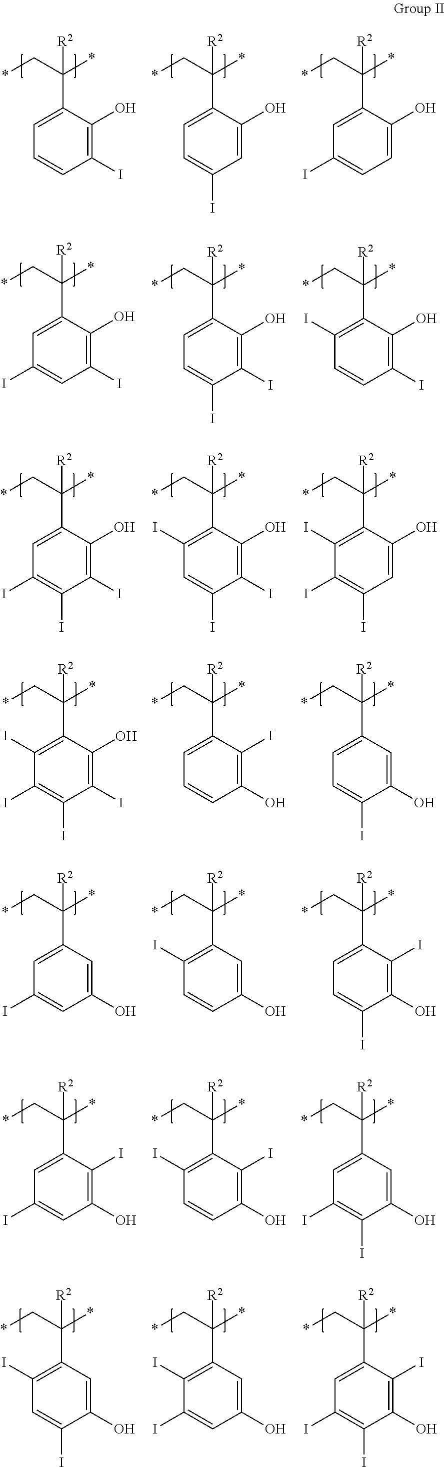

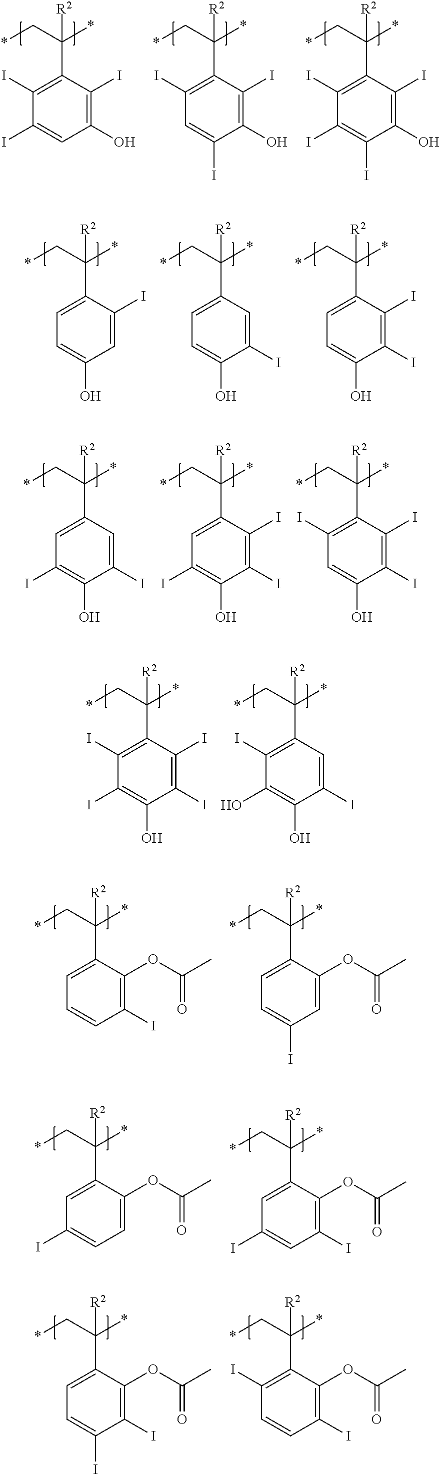

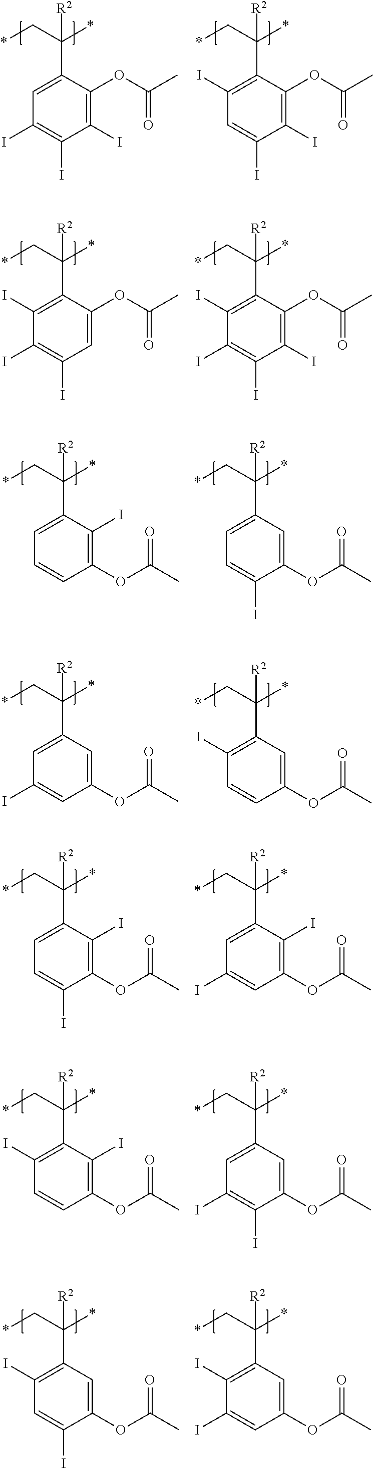

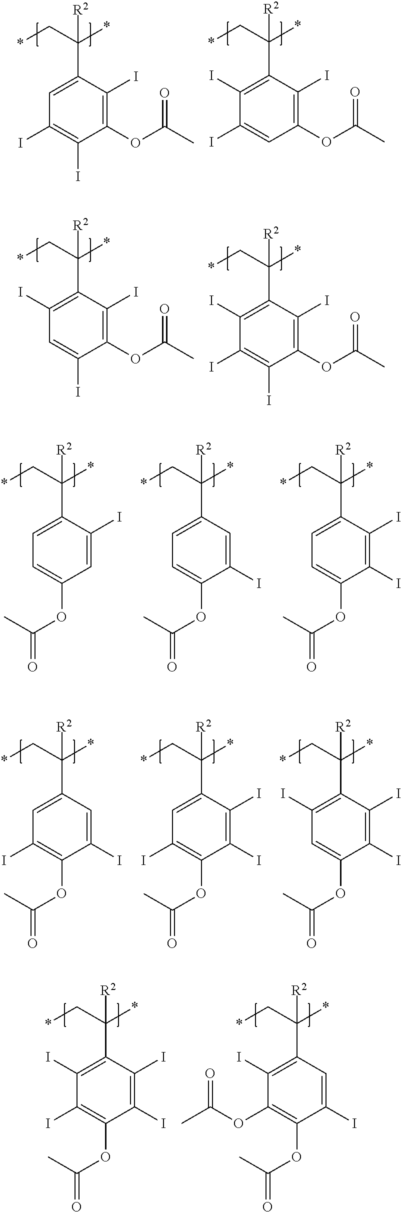

In Group II,
R² may each independently be hydrogen or a methyl group, and * may be a linking point.

For example, L³ to L⁹ may each independently be a single bond, a substituted or unsubstituted C1 to C5 alkylene group, or a substituted or unsubstituted phenylene group,
R¹⁰, R¹¹, R²⁰, and R²¹ may each independently be hydrogen, a hydroxyl group, a substituted or unsubstituted methyl group, a substituted or unsubstituted ethyl group, a substituted or unsubstituted n-propyl group, a substituted or unsubstituted isopropyl group, a substituted or unsubstituted n-butyl group, a substituted or unsubstituted tert-butyl group, a substituted or unsubstituted n-pentyl group, a substituted or unsubstituted neo-pentyl group, a substituted or unsubstituted phenyl group, NR^{c}R^{d} (wherein, R^{c} and R^{d} may each independently be hydrogen, deuterium, or a C1 to C10 alkyl group), or a combination thereof, and
R¹² to R¹⁹ may each independently be hydrogen, or a substituted or unsubstituted C1 to C10 alkyl group.

The third structural unit may be selected from among Group III (e.g., at least one selected from among the structural units in Group III).

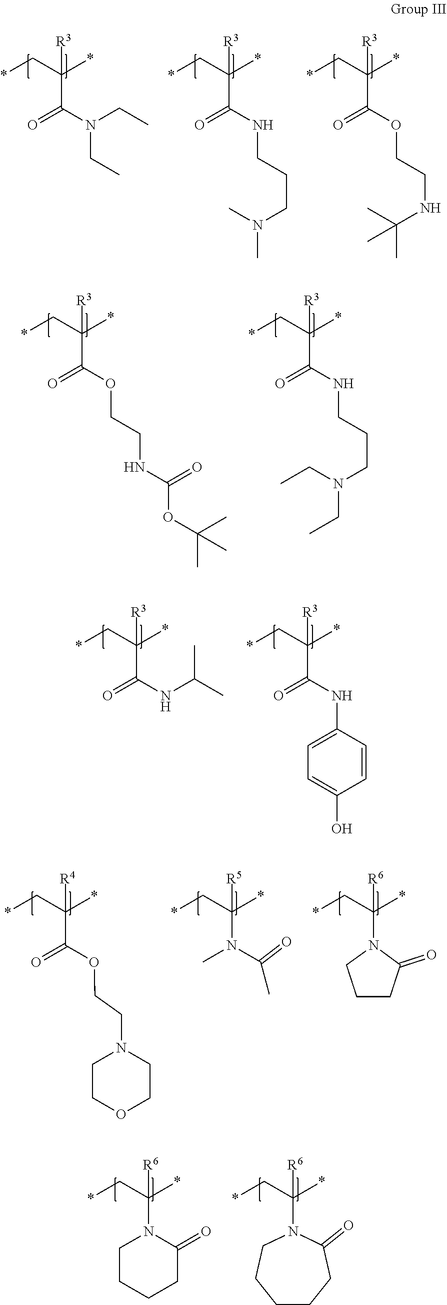

In Group III,
R³ to R⁶ may each independently be hydrogen or a methyl group, and * may be a linking point.

The copolymer may include 30 to 95 mol % of the first structural unit, about 1 to about 20 mol % of the second structural unit, and about 5 to about 50 mol % of the third structural unit, based on a total weight of the copolymer.

For example, the copolymer may include about 55 to about 90 mol % of the first structural unit, about 5 to about 15 mol % of the second structural unit, and about 5 to about 30 mol % of the third structural unit, and, for example, about 60 to about 85 mol % of the first structural unit, about 5 to about 15 mol % of the second structural unit, and about 5 to about 25 mol % of the third structural unit.

If (e.g., when) the mole ratio of each structural unit included in the acrylic copolymer is within the described range, solubility in an organic solvent is improved, and thus it may be uniformly coated on the pattern.

The copolymer may have a weight average molecular weight (Mw) of about 1,000 g/mol to about 50,000 g/mol. For example, it may have a weight average molecular weight of about 2,000 g/mol to about 30,000 g/mol, for example, about 3,000 g/mol to about 20,000 g/mol, or for example, about 4,000 g/mol to about 10,000 g/mol, but not limited thereto. If (e.g., when) the weight average molecular weight of the copolymer is within the described range, a carbon content (e.g., amount) and solubility in a solvent of the resist topcoat composition including the copolymer may be optimized.

The copolymer may be included in the resist topcoat composition in an amount of about 0.1 wt % to about 10 wt % based on a total weight of the resist topcoat composition. Within the described range, the resist topcoat may be easily removed.

The pH of the resist topcoat composition may be about 3 to about 12.

The solvent may be an ether-based solvent represented by Chemical Formula 4.

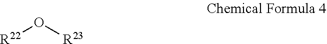

In Chemical Formula 4,
R²² and R²³ may each independently be a substituted or unsubstituted C3 to C20 alkyl group.

For example, the ether-based solvent may be selected from among diisopropyl ether, dipropyl ether, diisoamyl ether, diamyl ether, dibutyl ether, diisobutyl ether, di-sec-butyl ether, dihexyl ether, bis(2-ethylhexyl) ether, didecyl ether, diundecyl ether, didodecyl ether, ditetradecyl ether, hexadecyl ether, butyl methyl ether, butyl ethyl ether, butyl propyl ether, tert-butyl methyl ether, tert-butyl ethyl ether, tert-butylpropyl ether, di-tert-butyl ether, cyclopentylmethyl ether, cyclohexylmethyl ether, cyclopentylethyl ether, cyclohexylethyl ether, cyclopentylpropyl ether, cyclopentyl-2-propyl ether, cyclohexylpropyl ether, cyclohexyl-2-propyl ether, cyclopentylbutyl ether, cyclopentyl-tert-butyl ether, cyclohexylbutyl ether, cyclohexyl-tert-butyl ether, 2-octanone, 4-heptanone, and one or more combinations thereof.

The ether-based solvent may have sufficient solubility or dispersibility for the resist topcoat composition.

In some embodiments, the resist topcoat composition may further include at least one other polymer selected from among an epoxy-based resin, a novolac-based resin, a glycoluril-based resin, and a melamine-based resin, but is not limited thereto.

The resist topcoat composition may further include an additive including a surfactant, a thermal acid generator, a plasticizer, or a combination thereof.

The surfactant may be, for example, an alkylbenzenesulfonic acid salt, an alkylpyridinium salt, polyethylene glycol, a quaternary ammonium salt, and/or the like, but is not limited thereto.

The thermal acid generator may be, for example, an acid compound such as p-toluenesulfonic acid, trifluoromethanesulfonic acid, pyridinium p-toluenesulfonic acid, salicylic acid, sulfosalicylic acid, citric acid, benzoic acid, hydroxyl benzoic acid, naphthalenecarboxylic acid and/or benzointosylate, 2-nitrobenzyl tosylate, and other organic sulfonic acid alkyl esters, but is not limited thereto.

An amount of these additives utilized may be easily adjusted depending on the desired or suitable physical properties. In some embodiments, the additives may not be provided.

According to another embodiment, a method of forming a pattern utilizing the resist (e.g., photoresist) topcoat composition described herein may be provided. As an example, the manufactured pattern may be a photoresist pattern.

A method of forming patterns according to some embodiments includes coating a photoresist composition on a substrate and heating it to form a photoresist film, coating the aforementioned resist topcoat composition on the photoresist film and heating to form a photoresist topcoat, exposing and developing the photoresist topcoat and the photoresist film to form the patterns.

Hereinafter, a method of forming patterns utilizing the aforementioned resist (e.g., photoresist) topcoat composition will be described with reference to the drawing. The drawing is a schematic view for explaining a method of forming patterns utilizing the resist (e.g., photoresist) topcoat composition according to the present disclosure.

Referring to the drawing, an etching object is first prepared. Examples of the etching object may be a thin film formed on a semiconductor substrate. Hereinafter, only a case of utilizing a thin film 100 as the etching object will be described. In order to remove contaminants and/or the like remaining on the thin film, the surface of the thin film 100 is washed. The thin film 100 may be, for example, a silicon nitride film, a polysilicon film, or a silicon oxide film.

On the thin film 100, a photoresist composition is applied (e.g., coated) and heated to form a photoresist film 101 (e.g., shown at 1). Subsequently, on the photoresist film 101, the aforementioned resist (e.g., photoresist) topcoat composition is applied (e.g., coated) and heated to form a photoresist topcoat 30 (e.g., shown at 2).

The heating may be performed at about 80° C. to about 500° C.

Subsequently, the photoresist topcoat 30 and the photoresist film 101 are covered by a patterned mask and exposed to high-energy rays.

For example, the high-energy rays utilized in the exposure process may be light having a high energy wavelength such as EUV (Extreme UltraViolet; a wavelength of about 13.5 nm), E-beam (electron beam), and/or the like.

Subsequently, after the exposure, a heat treatment (PEB) is performed. The heat treatment after the exposure may be performed at about 80° C. to about 200° C. As the heat treatment is performed after the exposure, an exposed region in the photoresist film 101, (that is, chemical properties of a region not covered with the patterned mask), may be changed to a chemical composition that is soluble in a developer, so that the exposed region is dissolved by the developer and changed. In other words, the region has a different solubility from that of a non-exposed region of the photoresist film 101.

The photoresist film 101 and the photoresist topcoat 30 corresponding to the exposed region are dissolved by a developer to form a photoresist pattern 102b (e.g., shown at 3).

For example, the developer may be an alkaline developer or a developer including an organic solvent (hereinafter referred to as an organic developer).

The alkaline developer may generally include a quaternary ammonium salt such as tetramethylammonium hydroxide, but alkaline aqueous solutions such as inorganic alkalis, primary to tertiary amines, alcohol amines, and cyclic amines may also be utilized.

Additionally, the alkaline developer may include an appropriate or suitable amount of alcohol and/or surfactant. An alkali concentration of the alkaline developer may be, for example, about 0.1 to about 20 mass %, and pH of the alkaline developer may be, for example, about 10 to about 15.

The organic developer may be a developer including at least one organic solvent selected from among a ketone-based solvent, an ester-based solvent, an alcohol-based solvent, an amide-based solvent, an ether-based solvent, and a hydrocarbon-based solvent.

Examples of ketone-based solvent may include 1-octanone, 2-octanone, 1-nonanone, 2-nonanone, acetone, 2-heptanone (methyl amyl ketone), 4-heptanone, 1-hexanone, 2-hexanone, diisobutyl ketone, cyclohexanone, methylcyclohexanone, phenylacetone, methyl ethyl ketone, methyl isobutyl ketone, acetylacetone, acetonyl acetone, ionone, diacetonyl alcohol, acetyl carbinol, acetophenone, methylnaphthyl ketone, isophorone, and propylene carbonate.

Examples of the ester-based solvent may include methyl acetate, butyl acetate, ethyl acetate, isopropyl acetate, pentyl acetate, isopentyl acetate, amyl acetate, propylene glycol monomethyl ether acetate, and ethylene glycol monoethyl ether acetate, ehylene glycol monobutyl ether acetate, ethylene glycol monoethyl ether acetate, ethyl-3-ethoxypropionate, 3-methoxybutyl acetate, 3-methyl-3-methoxybutyl acetate, methyl formate, ethyl formate, butyl formate, propyl formate, ethyl lactate, butyl lactate, propyl lactate, butyl butanoate, methyl 2-hydroxyisobutyrate, isoamyl acetate, isobutyl isobutyrate, and butyl propionate.

Known solvents can be utilized as the alcohol-based solvent, amide-based solvent, ether-based solvent, and hydrocarbon-based solvent.

A plurality of the described solvents may be mixed, or they may be mixed with solvents other than the described solvents or water. A moisture content (e.g., amount) of the entire developer may be less than about 50 wt %, less than about 20 wt %, or less than about 10 wt %, or even the developer may substantially include no moisture.

A content (e.g., amount) of the organic solvent in the organic developer may be about 50 wt % to about 100 wt %, about 80 wt % to about 100 wt %, about 90 wt % to about 100 wt %, or about 95 to about 100 wt % based on a total amount of the organic developer.

The organic developer, if (e.g., when) necessary, may contain an appropriate or suitable amount of a suitable surfactant.

A content (e.g., amount) of the surfactant may be about 0.001 wt % to about 5 wt %, about 0.005 wt % to about 2 wt %, or about 0.01 wt % to about 0.5 wt % based on a total amount of the developer.

The organic developer may contain an appropriate or suitable inhibitor.

Subsequently, the thin film 100 exposed by applying an etching mask is etched to form photoresist patterns 102b. As a result, the thin film 100 is formed into thin film patterns.

The thin film 100 may be etched, for example, by dry etching utilizing an etching gas, and the etching gas may be, for example, CHF₃, CF₄, Cl₂, BCl₃, and a mixture thereof.

In the exposure process performed as described herein, the thin film pattern formed utilizing the photoresist pattern 102b that is formed by the exposure process performed utilizing the EUV light source may have a width corresponding to the photoresist pattern 102b. For example, the photoresist pattern 102b may have a width of about 5 nm to about 100 nm. For example, the thin film pattern formed by the exposure process performed utilizing an EUV light source may have a width of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, about 5 nm to about 20 nm, like the photoresist pattern 102b, and may be formed with (e.g., in) a width of less than or equal to about 20 nm.

Terms such as “substantially,” “about,” and “approximately” are used as relative terms and not as terms of degree, and are intended to account for the inherent deviations in measured or calculated values that would be recognized by those of ordinary skill in the art. They may be inclusive of the stated value and an acceptable range of deviation as determined by one of ordinary skill in the art, considering the limitations and error associated with measurement of that quantity. For example, “about” may refer to one or more standard deviations, or +30%, 20%, 10%, 5% of the stated value.

Numerical ranges disclosed herein include and are intended to disclose all subsumed sub-ranges of the same numerical precision. For example, a range of “1.0 to 10.0” includes all subranges having a minimum value equal to or greater than 1.0 and a maximum value equal to or less than 10.0, such as, for example, 2.4 to 7.6. Applicant therefore reserves the right to amend this specification, including the claims, to expressly recite any sub-range subsumed within the ranges expressly recited herein.

A display device, a display manufacturing device, a pattern forming device, and/or any other relevant devices or components according to embodiments of the present invention described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the present disclosure.

Hereinafter, the present disclosure will be described in more detail through examples relating to the synthesis of the aforementioned polymer and the preparation of a photoresist topcoat composition including the same. However, the present disclosure is not technically limited by the following examples.

### EXAMPLES

### Synthesis Example

### 1 Synthesis Example 1: Synthesis of Compound 1a

20 g (59.86 mmol) of hexafluoro-2,3-bis(trifluoromethyl)-2,3-butanediol (perfluoropinacol), 7.79 g (59.86 mmol) of 2-(hydroxyethyl) methacrylate, and 18.84 g (71.84 mmol) of triphenylphosphine (PH3P) were mixed in 110 mL of diethylether under a nitrogen atmosphere and then, stirred. After the stirring for 30 minutes, the mixture was cooled down to 0° C., and another mixture of 14.52 g (71.84 mmol) of diisopropylazodicarboxylate (DIAD) and 35 mL of diethylether was slowly added thereto over 2 hours. Subsequently, the obtained mixture was stirred at room temperature (23° C.) for 24 hours and then, concentrated. The concentrated mixture was dissolved in dichloromethane and then, treated through column chromatography by utilizing silica gel to separate a synthesized material. The separated material was distilled under a reduced pressure, obtaining 2-[3,3,3-trifluoro-2-hydroxy-1,1,2-tris(trifluoromethyl)propoxy]ethyl 2-methyl-2-propenoate represented by Chemical Formula 1a.

* ¹H-NMR (Acetone-d6): δ 1.90 (3H, t), 4.36 (4H, m), 5.63 (1H, t), 6.09 (1H, t), 8.34 (1H, s)

* ¹⁹F-NMR (Acetone-d6): δ-70.12 (6F, m), −65.38 (6F, m)

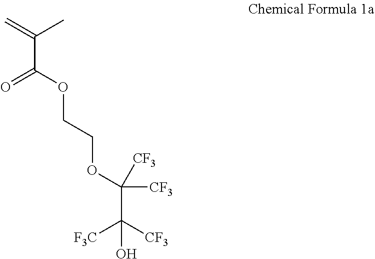 [SMILES: C=C(C)C(=O)OCCOC(C(F)(F)F)(C(F)(F)F)C(O)(C(F)(F)F)C(F)(F)F]

### Synthesis Example 2: Preparation of Copolymer (R1)

In a 250 mL 2-neck round bottom flask, a compound represented by Chemical Formula 1a (22.5 g, 50 mmol), a compound represented by Chemical Formula 1b (DIVPA, Songwon Industrial Co., Ltd.) (2.4 g, 6 mmol), a compound represented by Chemical Formula 1c (N,N-diethylmethacrylamide, Sigma-Aldrich Co., Ltd.) (2.3 g, 16 mmol), and 115 g of diisoamyl ether (DIAE) were put under a nitrogen atmosphere and then, heated to an internal temperature of 115° C. If (e.g., when) the internal temperature reached 115° C., 26.5 g of a 25 wt % V-601/DIAE solution (V-601: 6.6 g, 29 mmol) was slowly added thereto, and after 6 hours, the reaction solution was cooled to room temperature and then, concentrated to have 50% of a solid content (e.g., amount). To the concentrated solution, 270 g of heptane was added thereto, and a polymer produced therein was filtered. The filtered polymer was completely dissolved in 34 g of DIAE and then, precipitated by adding 270 g of heptane thereto, which procedure was repeated (e.g., repeated two times), and completely dried to finally prepare Copolymer R1 (Mw=7,000).

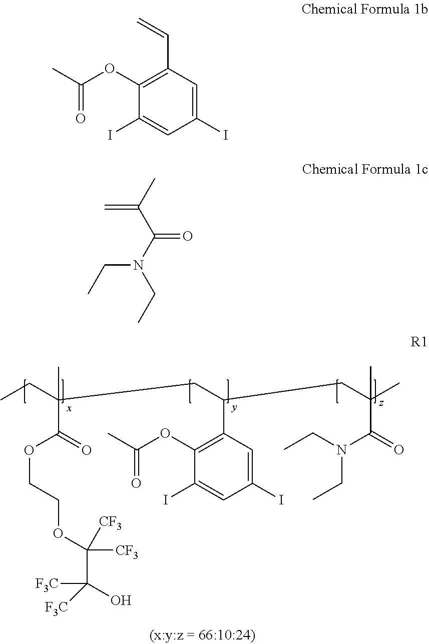

### Synthesis Example 3: Preparation of Copolymer (R2)

Copolymer R2 (Mw=7,000) was prepared in substantially the same manner as in Synthesis Example 2 except that a compound represented by Chemical Formula 2c (tert-butylaminoethyl methacrylate, Sigma-Aldrich Co., Ltd.) (2.9 g, 16 mmol) was utilized instead of the compound represented by Chemical Formula 1c.

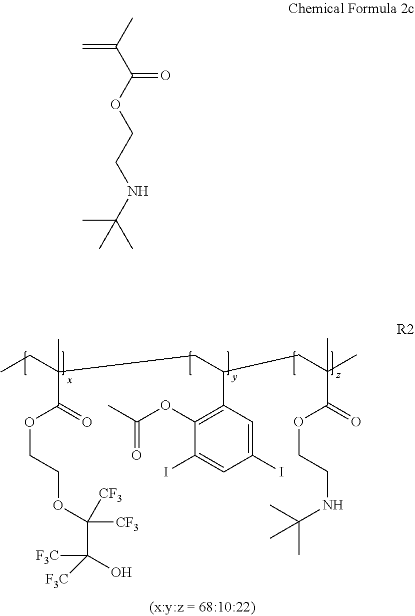

### Synthesis Example 4: Preparation of Copolymer (R3)

Copolymer R3 (Mw=7,000) was prepared in substantially the same manner as in Synthesis Example 2 except that a compound represented by Chemical Formula 3c (1-vinyl-2-pyrrolidinone, Sigma-Aldrich Co., Ltd.) (2.9 g, 16 mmol) was utilized instead of the compound represented by Chemical Formula 1c.

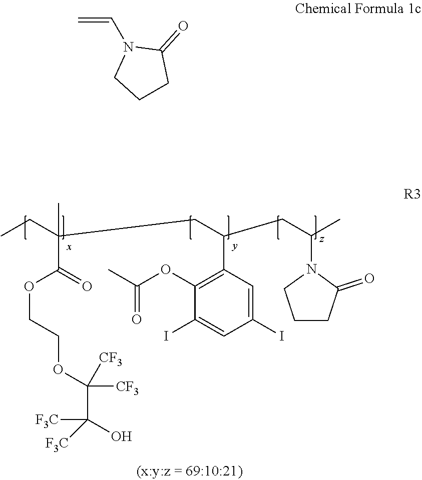

### Comparative Synthesis Example 1: Preparation of Copolymer R4

Copolymer R4 (Mw=6,000) was prepared in substantially the same manner as in Synthesis Example 2 except that a compound represented by Chemical Formula 4c (2-ethylhexyl methacrylate, Daejung Chemicals & Metals) (3.2 g, 16 mmol) was utilized instead of the compound represented by Chemical Formula 1c.

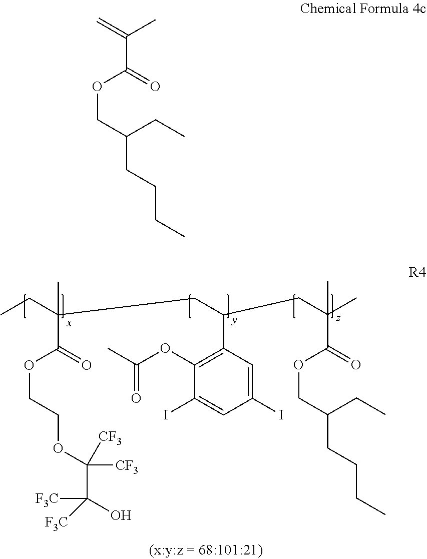

### Preparation of Resist Topcoat Composition

### Example 1

A resist topcoat composition of Example 1 was prepared by dissolving 0.5 wt % of Copolymer R1 of Synthesis Example 2 in 100 g of DIAE, stirring the solution at room temperature (23° C.) for 24 hours, and filtering it with TEFLON (tetrafluoroethylene) filter having a pore size of 0.45 micrometer (μm).

### Examples 2 and 3 and Comparative Example 1

Each resist topcoat composition was prepared in substantially the same manner as in Example 1 except that each copolymer of Synthesis Examples 3 and 4 and Comparative Synthesis Example 1 was utilized instead of Copolymer R1.

### 1 Evaluation 1: Evaluation of Solubility

1 g of each of the copolymers of Synthesis Examples 2 to 4 and Comparative Synthesis Example 1 was added to 50 g of DIAE (2 wt %) and then, stirred for 24 hours, and then, whether or not precipitates were produced there was examined, and the results are shown in Table 1.

In Table 1, occurrence of precipitation is indicated by “solubility o”, and no precipitation is indicated by “solubility X”.

### Evaluation 2: Evaluation of Developability

Each of the photoresist topcoat compositions of Examples 1 to 3 and Comparative Example 1 was spin-coated on a silicon substrate and heat-treated at 110° C. for 1 minutes on a hot plate to form an about 5 nanometer (nm)-thick photoresist topcoat. Subsequently, the coated substrate was rinsed with a 2.38% tetramethylammonium hydroxide aqueous solution and heat-treated at 110° C. for 1 minute on a hot plate to measure a thickness change of the topcoat, and the results are shown in Table 1.

* Residual film after development (%)=[thickness (nm) of topcoat before development−thickness (nm) of topcoat after development]×100/thickness (nm) of topcoat before development

In Table 1, a residual film after development ≤20% is indicated by “developability O”, and a residual film after development >20% is indicated by “developability X”.

### Evaluation 3: Evaluation of Sensitivity and LWR

After forming a resist underlayer (thickness: 50 angstrom (Å)) and a photoresist thin film for E-beam (thickness: 700 Å) on an 8-inch silicon substrate, each of the photoresist topcoat compositions according to the examples and the comparative examples was spin-coated and heat-treated at 110° C. for 1 minutes on a hot plate to form an about 5 nm-thick photoresist topcoat.

In the wafer on which the photoresist topcoat was formed, line & space patterns were formed in a focus-energy matrix (FEM) format by utilizing E-beam equipment (JBX-9300FS, JEOL Ltd.). Optimal sensitivity capable of forming a critical dimension (CD) of 50 nm was checked in an interpolation method, reported in millijoule per square centimeter (mJ/cm²), and the results are shown in Table 1.

After checking the optimal or suitable sensitivity, a line width roughness (LWR) distribution was measured at the corresponding energy shot by utilizing CD-SEM equipment (Hitatchi, Ltd.), wherein in order to increase reliability of the distribution, the same patterns were measured at 500 points within the shot and then, averaged, and the results are shown in Table 1.

TABLE 1

| | | | | Sensitivity | LWR |
|---|---|---|---|---|---|
| | Copolymer | Solubility | Developability | (mJ/cm²) | (nm) |
| Example 1 | R1 | ◯ | ◯ | 2100 | 2.12 |
| Example 2 | R2 | ◯ | ◯ | 1900 | 2.25 |
| Example 3 | R3 | ◯ | ◯ | 2000 | 2.16 |
| Comparative | R4 | ◯ | X | 2300 | 2.55 |
| Example 1 | | | | | |

Referring to Table 1, if (e.g., when) the resist topcoat compositions of the examples were applied, excellent or suitable solubility, developability, and sensitivity were not only obtained, but also excellent or suitable LWR improvement effect was achieved by suppressing the pattern deterioration.

In contrast, the resist topcoat compositions of the comparative example exhibited relatively deteriorated developability and sensitivity and no LWR improvement effect.

Hereinbefore, the certain embodiments of the present disclosure have been described and illustrated, however, it is apparent to a person with ordinary skill in the art that the present disclosure is not limited to the embodiment as described, and may be variously modified and transformed without departing from the spirit and scope of the present disclosure. Accordingly, the modified or transformed embodiments as such may not be understood separately from the technical ideas and aspects of the present disclosure, and the modified embodiments are within the scope of the claims, and equivalents thereof.

### DESCRIPTION OF SYMBOLS

1: forming a photoresist film
2: forming a photoresist topcoat
3: exposing and developing the photoresist film and photoresist topcoat to form a resist pattern.
30: photoresist topcoat
100: thin film
101: photoresist film
102b: photoresist pattern

What is claimed is:

1. A resist topcoat composition, comprising
a copolymer comprising
a first structural unit represented by Chemical Formula M-1,
a second structural unit represented by Chemical Formula M-2, and
a third structural unit comprising at least one selected from among structural units represented by Chemical Formula M-3A, Chemical Formula M-3B, Chemical Formula M-3C, and Chemical Formula M-3D; and
a solvent: 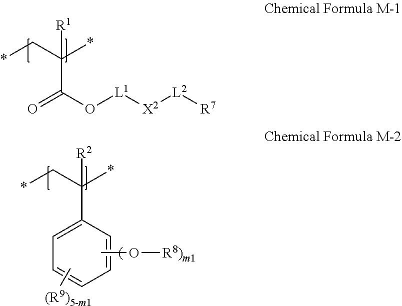
wherein, in Chemical Formula M-1 and Chemical Formula M-2,
R¹ and R² are each independently hydrogen or a substituted or unsubstituted C1 to C10 alkyl group,
L¹ and L² are each independently a single bond, a substituted or unsubstituted C1 to C10 alkylene group, or a combination thereof,
X¹ is a single bond, O, S, S(O), S(O)₂, C(O), (CO)O, O(CO), O(CO)O, NR^{a} (wherein, R^{a} is hydrogen, deuterium, or a C1 to C10 alkyl group), or a combination thereof,
R⁷ is hydrogen, fluorine, a hydroxyl group, a substituted or unsubstituted C1 to C20 alkyl group, or a combination thereof,
R⁸ are each independently hydrogen, or C(═O)R^{b},
R^{b} is a substituted or unsubstituted C1 to C10 alkyl group,
at least one of R⁷, L¹, or L² comprises fluorine and a hydroxyl group,
R⁹ are each independently hydrogen, a halogen, a hydroxyl group, a substituted or unsubstituted C1 to C10 alkyl group, or a combination thereof, and
m1 is an integer of 1 to 4, 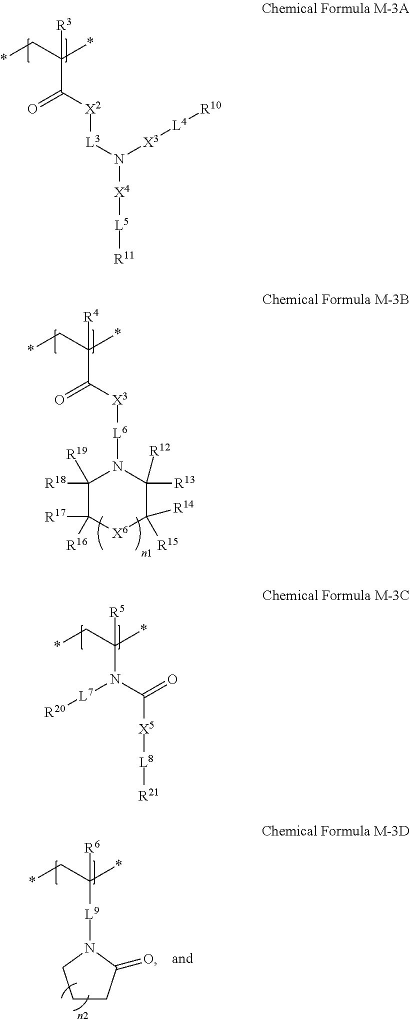
wherein, in Chemical Formula M-3A to Chemical Formula M-3D,
R³ to R⁶ are each independently hydrogen or a substituted or unsubstituted C1 to C10 alkyl group,
R¹⁰ and R¹¹ are each independently hydrogen, a hydroxyl group, a substituted or unsubstituted C1 to C20 alkyl group, a substituted or unsubstituted C6 to C20 aryl group, NR^{c}R^{d} (wherein, R^{c} and R^{d} are each independently hydrogen, deuterium, or a C1 to C10 alkyl group), or a combination thereof,
R¹² to R²¹ are each independently hydrogen, a substituted or unsubstituted C1 to C20 alkyl group, a substituted or unsubstituted C6 to C20 aryl group, NR^{c}R^{d} (wherein, R^{c} and R^{d} are each independently hydrogen, deuterium, or a C1 to C10 alkyl group), or a combination thereof,
L³ to L⁹ are each independently a single bond, a substituted or unsubstituted C1 to C10 alkylene group, a substituted or unsubstituted C6 to C12 arylene group, or a combination thereof,
X² and X⁵ are each independently a single bond, O, or S,
X³ and X⁴ are each independently a single bond, (CO)O, O(CO), or O(CO)O,
X⁶ is a single bond, O, or CH₂,
n1 is an integer of 0 or 1,
n2 is an integer of 1 to 3, and
* is a linking point.

2. The resist topcoat composition of claim 1, wherein
the first structural unit is represented by Chemical Formula 1: 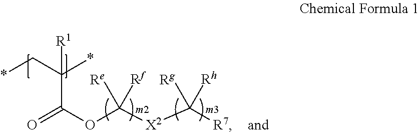
wherein, in Chemical Formula 1,
R¹ is hydrogen or a substituted or unsubstituted C1 to C10 alkyl group,
R^{e}, R^{f}, R^{g}, R^{h}, and R⁷ are each independently hydrogen, fluorine, a hydroxyl group, a substituted or unsubstituted C1 to C20 alkyl group, or a combination thereof,
m2 and m3 are each independently one selected from among integers of 1 to 10,
X¹ is a single bond, O, S, S(O), S(O)₂, C(O), (CO)O, O(CO), O(CO)O, NR^{a} (wherein, R^{a} is hydrogen, deuterium, or a C1 to C10 alkyl group), or a combination thereof, and
at least one of R^{e}, R^{f}, R^{g}, R^{h}, or R⁷ comprises fluorine and a hydroxyl group.

3. The resist topcoat composition as claimed in claim 2, wherein
at least one of R^{g}, R^{h}, or R⁷ comprises one or more fluorine and one or more hydroxyl groups.

4. The resist topcoat composition as claimed in claim 2, wherein
in Chemical Formula 1, at least one of R^{g} or R^{h} is fluorine or a C1 to C10 alkyl group substituted with at least one fluorine, and
R⁷ is a hydroxyl group or a C1 to C10 alkyl group substituted with at least one hydroxyl group.

5. The resist topcoat composition as claimed in claim 2, wherein
in Chemical Formula 1, at least one of R^{g} or R^{h} is a hydroxyl group or a C1 to C10 alkyl group substituted with at least one hydroxyl group, and
R⁷ is a fluorine or a C1 to C10 alkyl group substituted with at least one fluorine.

6. The resist topcoat composition as claimed in claim 2, wherein
in Chemical Formula 1, R⁹ is a hydroxyl group or a C1 to C10 alkyl group substituted with at least one hydroxyl group,
R^{h} is fluorine or a C1 to C10 alkyl group substituted with at least one fluorine, and
R⁷ is a hydroxyl group, fluorine, or a C1 to C10 alkyl group substituted with at least one of one or more fluorine or one or more hydroxyl groups.

7. The resist topcoat composition as claimed in claim 2, wherein
in Chemical Formula 1, at least one of R^{g} or R^{h} is fluorine or a C1 to C10 alkyl group substituted with at least one fluorine, and
R⁷ is a hydroxyl group, or a C1 to C5 alkyl group substituted with at least one of one or more hydroxyl groups and one or more C1 to C5 fluoroalkyl groups.

8. The resist topcoat composition as claimed in claim 1, wherein
the first structural unit is selected from among Group I: 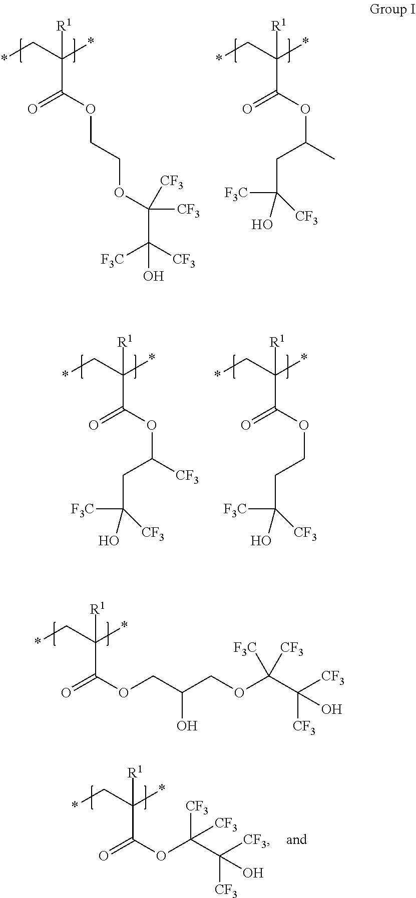
wherein, in Group I,
R¹ are each independently hydrogen or a methyl group, and * is a linking point.

9. The resist topcoat composition as claimed in claim 1, wherein
the second structural unit is represented by any one of Chemical Formula 2-1 to Chemical Formula 2-4: 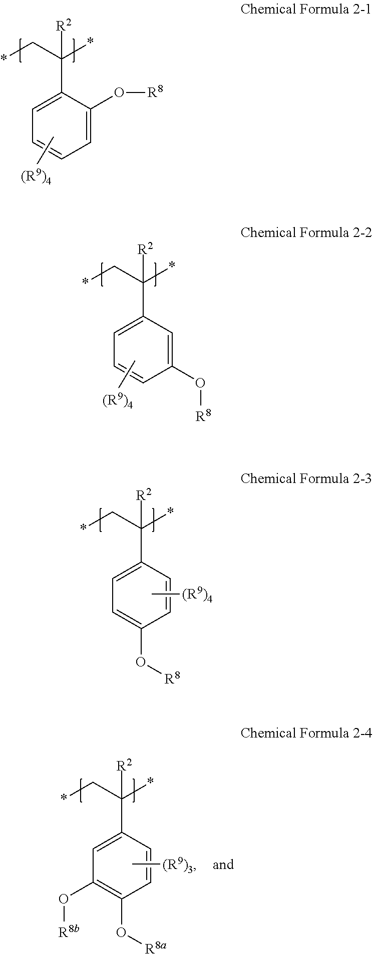
wherein, in Chemical Formula 2-1 to Chemical Formula 2-4,
R² is hydrogen or a methyl group,
R⁸, R^{8a}, and R^{8b} are each independently hydrogen, or C(═O)R^{b},
R^{b} is a substituted or unsubstituted C1 to C5 alkyl group,
m1 is one selected from among integers of 1 to 4,
R⁹ are each independently hydrogen, a halogen, a hydroxyl group, a substituted or unsubstituted C1 to C10 alkyl group, or a combination thereof, and
* is a linking point.

10. The resist topcoat composition as claimed in claim 1, wherein
at least one of R⁹ is a halogen.

11. The resist topcoat composition as claimed in claim 1, wherein
at least one of R⁹ is an iodine group.

12. The resist topcoat composition as claimed in claim 1, wherein
the second structural unit is selected from among Group II: 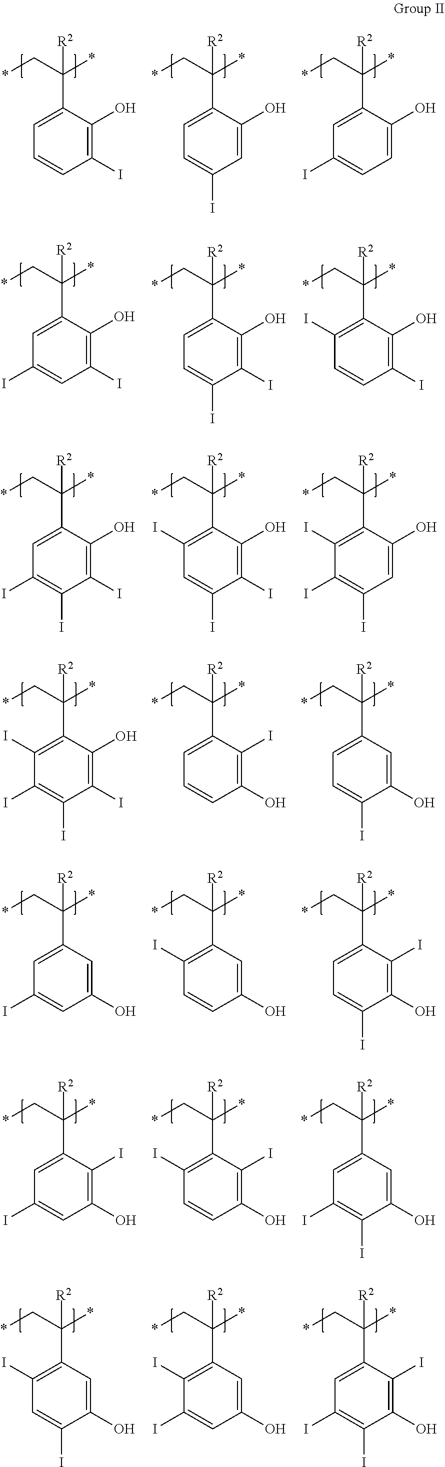 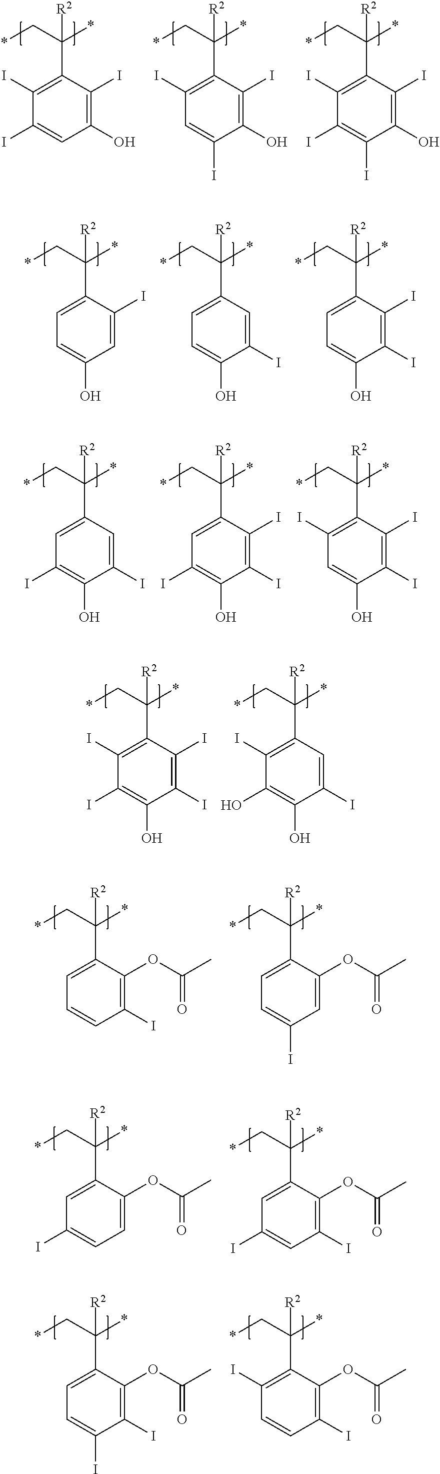 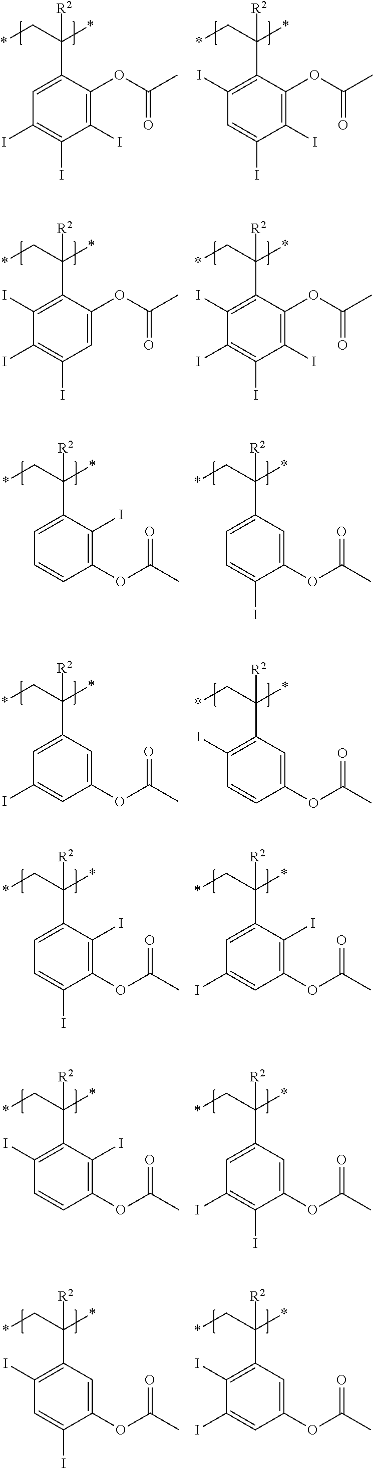 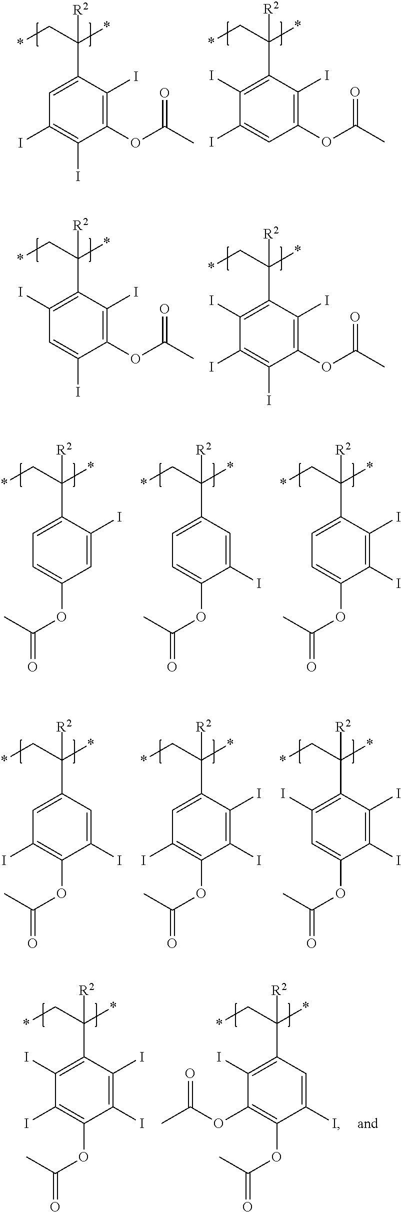
wherein, in Group II,
R² are each independently hydrogen or a methyl group, and * is a linking point.

13. The resist topcoat composition as claimed in claim 1, wherein
L³ to L⁹ are each independently a single bond, a substituted or unsubstituted C1 to C5 alkylene group, or a substituted or unsubstituted phenylene group,
R¹⁰, R¹¹, R²⁰, and R²¹ are each independently hydrogen, a hydroxyl group, a substituted or unsubstituted methyl group, a substituted or unsubstituted ethyl group, a substituted or unsubstituted n-propyl group, a substituted or unsubstituted isopropyl group, a substituted or unsubstituted n-butyl group, a substituted or unsubstituted tert-butyl group, a substituted or unsubstituted n-pentyl group, a substituted or unsubstituted neo-pentyl group, a substituted or unsubstituted phenyl group, NR^{c}R^{d} (wherein, R^{c} and R^{d} are each independently hydrogen, deuterium, or a C1 to C10 alkyl group), or a combination thereof, and
R¹² to R¹⁹ are each independently hydrogen, or a substituted or unsubstituted C1 to C10 alkyl group.

14. The resist topcoat composition as claimed in claim 1, wherein
the third structural unit is at least one selected from among Group III: 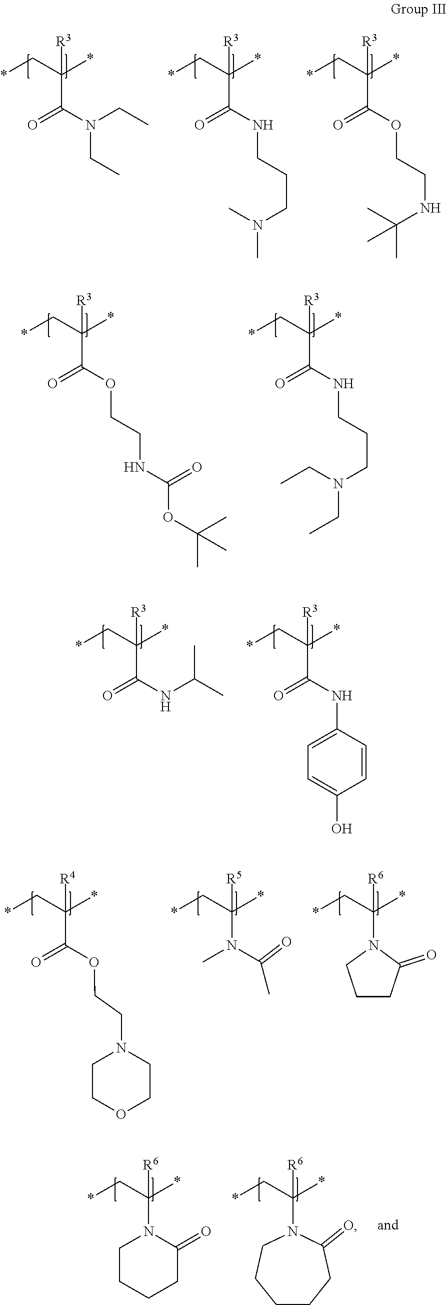
wherein, in Group III,
R³ to R⁶ are each independently hydrogen or a methyl group, and * is a linking point.

15. The resist topcoat composition as claimed in claim 1, wherein
the copolymer comprises about 30 to 95 mol % of the first structural unit, about 1 to about 20 mol % of the second structural unit, and about 5 to about 50 mol % of the third structural unit, based on a total weight of the copolymer.

16. The resist topcoat composition of claim 1, wherein
a weight average molecular weight of the copolymer is about 1,000 g/mol to about 50,000 g/mol.

17. The resist topcoat composition as claimed in claim 1, wherein
the resist topcoat composition comprises about 0.1 wt % to about 10 wt % of the copolymer, based on a total weight of the resist topcoat composition.

18. The resist topcoat composition as claimed in claim 1, wherein
a pH of the resist topcoat composition is about 3 to about 12.

19. The resist topcoat composition as claimed in claim 1, wherein
the solvent is an ether-based solvent represented by Chemical Formula 4: 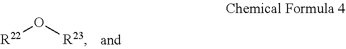
wherein, in Chemical Formula 4,
R²² and R²³ are each independently a substituted or unsubstituted C3 to C20 alkyl group.

20. A method of forming patterns, the method comprising:
coating a photoresist composition on a substrate and heating to form a photoresist film,
coating the resist topcoat composition as claimed in claim 1 on the photoresist film and heating to form a photoresist topcoat, and
exposing and developing the photoresist topcoat and the photoresist film to form the patterns.
